(19) United States
(12) Patent Application Publication
(10) Pub. No.: US 2024/0324358 A1
(43) Pub. Date: Sep. 26, 2024

(54) DISPLAY PANEL

(71) Applicant: Samsung Display Co., Ltd., Yongin-si (KR)

(72) Inventors: PILSUK LEE, Yongin-si (KR); YOOMIN KO, Yongin-si (KR); SUNHO KIM, Yongin-si (KR); Hyewon KIM, Yongin-si (KR); JUCHAN PARK, Yongin-si (KR); CHUNG SOCK CHOI, Yongin-si (KR); SUNGJIN HONG, Yongin-si (KR)

(73) Assignee: Samsung Display Co., Ltd., Yongin-si (KR)

(21) Appl. No.: 18/607,016

(22) Filed: Mar. 15, 2024

(30) Foreign Application Priority Data
Mar. 20, 2023 (KR) 10-2023-0036056

(51) Int. Cl. H10K 59/131

(52) U.S. Cl. CPC H10K 59/131

(57) ABSTRACT

A display panel is provided. The display panel includes a light emitting portion including an anode, a cathode, and an organic layer disposed between the anode and the cathode and that emits light. The display panel further includes a pixel driver electrically connected to the light emitting portion, and including a first transistor, a connection wire disposed on a layer different than the first transistor, and electrically connecting the light emitting portion and the pixel driver, and a conductive pattern disposed between the first transistor and the light emitting portion. The conductive pattern overlaps at least a portion of the anode and at least a portion of a gate of the first transistor in a plan view.

### CROSS-REFERENCE TO RELATED APPLICATIONS

This U.S. non-provisional patent application claims priority to and benefits of Korean Patent Application No. 10-2023-0036056 under 35 U.S.C. § 119, filed on Mar. 20, 2023 in the Korean Intellectual Property Office, the entire contents of which are hereby incorporated by reference.

### BACKGROUND

### 1. Technical Field

The disclosure relates to a display panel with improved image quality.

### 2. Description of the Related Art

Multimedia electronic devices such as televisions, mobile phones, tablet computers, computers, navigation system units, and game consoles are equipped with a display panel for displaying images.

The display panel includes a light emitting element and a driving circuit for driving the light emitting element. Light emitting portions included in the display panel emit light and generate images in response to a voltage applied from the circuit. In order to improve the reliability of the display panel, research is underway on the connection of the light emitting element and the driving circuit.

### SUMMARY

The disclosure relates to a display panel for displaying improved image quality.

An embodiment of the disclosure provides a display panel that may include a light emitting portion including an anode, a cathode, and an organic layer disposed between the anode and the cathode and that emits light. The display panel may further include a pixel driver electrically connected to the light emitting portion, and having a first transistor, a connection wire disposed on a layer different than the first transistor, and electrically connecting the light emitting portion and the pixel driver, and a conductive pattern disposed between the first transistor and the light emitting portion. The conductive pattern may overlap at least a portion of the anode and at least a portion of a gate of the first transistor in a plan view.

In an embodiment, the conductive pattern may receive a constant voltage.

In an embodiment, the conductive pattern and the anode may receive a same voltage.

In an embodiment, the conductive pattern and the cathode may receive a same voltage.

In an embodiment, the organic layer may include a light emitting pattern, and the light emitting pattern may be spaced apart from the conductive pattern in a plan view.

In an embodiment, the connection wire may extend in a first direction, and the conductive pattern may extend in a second direction intersecting the first direction.

In an embodiment, the first transistor and the light emitting portion may each be provided in plurality and arranged along a first direction, first transistors may be respectively electrically connected to light emitting portions different from each other, and the conductive pattern may overlap gates of the first transistors in a plan view.

In an embodiment, the conductive pattern and the connection wire may be disposed in a same layer, and the conductive pattern may be spaced apart from the connection wire in a plan view.

In an embodiment, the conductive pattern may be disposed in a layer different than the connection wire.

In an embodiment, the anodes of the light emitting portions may be connected to each other and have shape of a single body.

In an embodiment, the display panel may further include a gate driver (which may refer to the panel driver hereinafter) that provides a gate signal to pixel drivers corresponding to the light emitting portions, wherein a subset of the light emitting portions may overlap the gate driver in a plan view.

In an embodiment, the subset of the light emitting portions may be spaced apart from the conductive pattern in a plan view.

In an embodiment, a plurality of connection wires electrically connected to the light emitting portions and the pixel drivers corresponding to the light emitting portions may include a first connection wire electrically connected to a light emitting portion among the light emitting portions which is disposed in a first region spaced apart from the gate driver, a second connection wire electrically connected to a light emitting portion among the light emitting portions which is disposed in a second region more adjacent to the gate driver than the first region, and a third connection wire electrically connected to a light emitting portion among the light emitting portions which is disposed in a third region positioned between the first region and the second region in the first direction, and a length of the second connection wire may be greater than a length of the first connection wire.

In an embodiment, the first transistor may include an N-type semiconductor.

In an embodiment, the pixel driver may further include a second transistor electrically connected to the connection wire and spaced apart from the first transistor.

In an embodiment of the disclosure, a display panel may include a driving element layer including a plurality of pixel drivers each having a first transistor, a light emitting element layer disposed on the driving element layer, and including a separator and a plurality of light emitting elements, a plurality of connection wires each including a side electrically connected to a corresponding one of the plurality of light emitting elements and another side electrically connected to a corresponding one of the plurality of pixel drivers, and a conductive pattern disposed between the driving element layer and the light emitting element layer, and overlapping transistors of the plurality of pixel drivers in a plan view. Each one of the plurality of light emitting elements may include an anode, an organic layer disposed on the anode and separated from an adjacent light emitting portion by the separator, and a cathode disposed on the organic layer and separated from an adjacent light emitting portion by the separator layer, and the plurality of connection wires may be respectively electrically connected to cathodes of the plurality of light emitting elements.

In an embodiment, a side surface of the another side of each of the connection wires may have an undercut shape on a cross-section, and the cathode of each of the light emitting elements may be electrically connected to the side surface.

In an embodiment, a gate of each of the first transistors may be extended in a first direction, and the conductive pattern may be extended in a second direction intersecting the first direction.

In an embodiment, the conductive pattern may overlap, in a plan view, a plurality of gates arranged along the second direction among the respective gates of the first transistors.

In an embodiment, the conductive pattern may include a plurality of patterns arranged along the second direction, wherein the plurality of patterns may respectively overlap, in a plan view, the plurality of gates arranged along the second direction among the respective gates of the transistors.

In an embodiment, the anodes of the light emitting portions may be connected to each other and have shape of a single body.

In an embodiment, the conductive pattern and the connection wires may be disposed in a same layer, and the conductive pattern may be spaced apart from the connection wires in a plan view.

In an embodiment, the anode of each of the light emitting elements may be provided with a first voltage, and the conductive pattern may receive the first voltage.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain principles of the disclosure. In the drawings:

FIG. 1 is a schematic block diagram of a display device according to an embodiment of the disclosure;

FIG. 2A to FIG. 2D are schematic diagrams of equivalent circuits of a pixel according to an embodiment of the disclosure;

FIG. 3A and FIG. 3B are schematic plan views illustrating a display panel according to an embodiment of the disclosure;

FIG. 4A and FIG. 4B are schematic views illustrating a display panel according to an embodiment of the disclosure;

FIG. 5A to FIG. 5D are schematic plan views illustrating a portion of a display panel according to an embodiment of the disclosure;

FIG. 6 is a schematic cross-sectional view illustrating a portion of a display panel according to an embodiment of the disclosure;

FIG. 7A and FIG. 7B are schematic plan views of a display panel according to an embodiment of the disclosure;

FIG. 8A to FIG. 8C are schematic cross-sectional views of a display panel according to an embodiment of the disclosure;

FIG. 9A is a schematic plan view illustrating a portion of a display panel according to an embodiment of the disclosure;

FIG. 9B is a schematic perspective view illustrating a portion of the display panel illustrated in FIG. 9A;

FIG. 9C is a schematic plan view of one light emitting unit and one driving unit which are illustrated in FIG. 9A;

FIG. 10A is a schematic view illustrating one row of light emitting units and one row of driving units connected to the one row of the light emitting units;

FIG. 10B is a schematic plan view illustrating a partial region of a display panel according to an embodiment of the disclosure; and

FIG. 11A to FIG. 11C are schematic plan views illustrating a portion of a display panel according to an embodiment of the disclosure.

### DETAILED DESCRIPTION OF THE EMBODIMENTS

The disclosure will now be described more fully hereinafter with reference to the accompanying drawings, in which embodiments are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

In the drawings, like reference numerals refer to like elements. Also, in the drawings, the thickness, the ratio, and the dimensions of elements may be exaggerated for an effective description of technical contents.

As used herein, the singular forms, “a,” “an,” and “the” are intended to include the plural forms as well, unless the context clearly indicates otherwise.

In the disclosure, when an element (or a region, a layer, a portion, etc.) is referred to as being “on,” “connected to,” or “coupled to” another element, it means that the element may be directly disposed on/connected to/coupled to the other element, or that a third element may be disposed therebetween.

It will be understood that the terms “connected to” or “coupled to” may include a physical and/or electrical connection or coupling.

In the specification and the claims, the term “and/or” is intended to include any combination of the terms “and” and “or” for the purpose of its meaning and interpretation. For example, “A and/or B” may be understood to mean any combination including “A, B, or A and B.” The terms “and” and “or” may be used in the conjunctive or disjunctive sense and may be understood to be equivalent to “and/or.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the disclosure.

In addition, terms such as “below,” “lower,” “above,” “upper,” and the like are used to describe the relationship of components shown in the drawings. The terms are used as a relative concept and are described with reference to the direction (i.e. first to third directions DR1, DR2, and DR3) indicated in the drawings.

The term “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

When an element is described as “not overlapping” or to “not overlap” another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

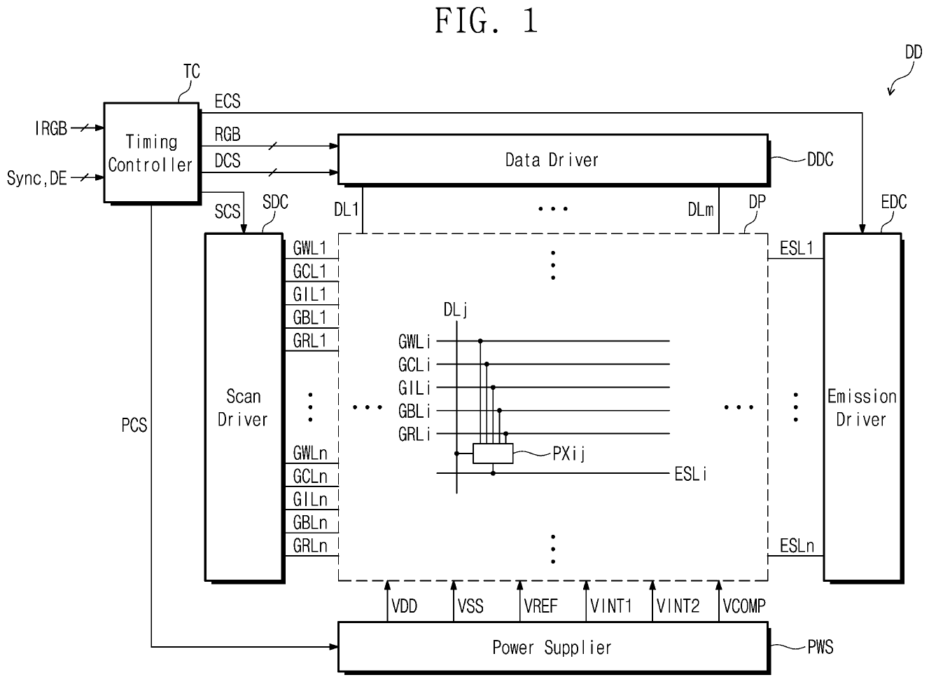

FIG. 1 is a schematic block diagram of a display device according to an embodiment of the disclosure. Referring to FIG. 1, a display device DD may include a display panel DP, panel drivers (e.g. a scan driver SDC, an emission driver EDC, and a data driver DDC), a power supplier PWS, and a timing controller TC. In an embodiment, the display panel DP will be described as being a light emitting-type display panel. The light emitting-type display panel DP may include an organic light emitting display panel, an inorganic light emitting display panel, or a quantum-dot light emitting display panel. In an embodiment to be described later, an organic light emitting display panel will be described in detail as an example. The panel drivers may include a scan driver SDC, an emission driver EDC, and a data driver DDC.

The display panel DP may include scan lines GWL1 to GWLn, GCL1 to GCLn, GIL1 to GILn, GBL1 to GBLn, and GRL1 to GRLn, emission lines ESL1 to ESLn, and data lines DL1 to DLm. The display panel DP may include multiple pixels connected to the scan lines GWL1 to GWLn, GCL1 to GCLn, GIL1 to GILn, GBL1 to GBLn, and GRL1 to GRLn, the emission lines ESL1 to ESLn, and the data lines DL1 to DLm (wherein, m and n are integers greater than 1).

For example, a pixel PXij (wherein, i and j are integers greater than 1) positioned on an i-th horizontal line (or, an i-th pixel row) and a j-th vertical line (or, a j-th pixel column) may be connected to an i-th first scan line GWLi (or a write scan line GWLi), an i-th second scan line GCLi (or a compensation scan line GCLi), an i-th third scan line GILi (or a first initialization scan line GILi), an i-th fourth scan line GBLi (or a second initialization scan line GBLi), an i-th fifth scan line GRLi (or a reset scan line GRLi), a j-th data line DLj, and an i-th emission line ESLi (or an emission line ESLi).

The pixel PXij may include at least one light emitting element, multiple transistors, and at least one capacitors. The pixel PXij may be supplied with a first power voltage VDD, a second power voltage VSS, a third power voltage VREF (or a reference voltage VREF), a fourth power voltage VINT1 (or a first initialization voltage VINT1), a fifth power voltage VINT2 (or a second initialization voltage VINT2), and a sixth power voltage VCOMP (or a compensation voltage VCOMP) through the power supplier PWS. A power voltage provided from the power supplier PWS may be a constant voltage.

The voltage values of the first power voltage VDD and the second power voltage VSS may be set such that a current flows through a light emitting element to emit light. For example, the first power voltage VDD may be set to a voltage higher than the second power voltage VSS.

The third power voltage VREF may be a voltage for initializing a gate of a driving transistor included in the pixel PXij. The third power voltage VREF may be used to implement a predetermined or selected gray scale by using a voltage difference with a data signal. To this end, the third power voltage VREF may be set to a predetermined or selected voltage within a voltage range of the data signal.

The fourth power voltage VINT1 may be a voltage for initializing a capacitor included in the pixel PXij. The fourth power voltage VINT1 may be set to a voltage lower than the third power voltage VREF. For example, the fourth power voltage VINT1 may be set to a voltage lower than a difference between the third power voltage VREF and a threshold voltage of the driving transistor. However, the disclosure is not limited thereto.

The fifth power voltage VINT2 may be a voltage for initializing a cathode of a light emitting element included in the pixel PXij. The fifth power voltage VINT2 may be set to a voltage lower than the first power voltage VDD or the fourth power voltage VINT1 or may be set to a voltage similar to or the same as the third power voltage VREF, but embodiments of the disclosure are not limited thereto, and the fifth power voltage VINT2 may be set to a voltage similar to or the same as the first power voltage VDD. The sixth power voltage VCOMP may supply a predetermined or selected current to the driving transistor in case that the threshold voltage of the driving transistor is compensated.

FIG. 1 illustrates that the first to sixth power voltages VDD, VSS, VREF, VINT1, VINT2, and VCOMP are all supplied from the power supplier PWS, but embodiments of the disclosure are not limited thereto. For example, the first power voltage VDD and the second power voltage VSS may be supplied regardless of a structure of the pixel PXij, and at least one voltage of the third power voltage VREF, the fourth power voltage VINT1, the fifth power voltage VINT2, and the sixth power voltage VCOMP may not be supplied in correspondence to the structure of the pixel PXij. In an embodiment of the disclosure, signal lines connected to the pixel PXij may be variously set in correspondence to a circuit structure of the pixel PXij.

The scan driver SDC may receive a first control signal SCS from the timing controller TC, and may supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn based on the first control signal SCS.

The scan signal may be set to a voltage at which transistors which are supplied with the scan signal may be turned on. For example, a scan signal supplied to a P-type transistor may be set to a logic low level, and a scan signal supplied to an N-type transistor may be set to a logic high level. Hereinafter, the meaning of “a scan signal is supplied” may be understood as that a scan signal is supplied at a logic level which turns on a transistor controlled by the scan signal.

In FIG. 1, for convenience of description, the scan driver SDC is illustrated as having a single configuration, but embodiments of the disclosure are not limited thereto. According to an embodiment, multiple scan drivers SDC may be included to supply a scan signal to each of the first scan lines GWL1 to GWLn, the second scan lines GCL1 to GCLn, the third scan lines GIL1 to GILn, the fourth scan lines GBL1 to GBLn, and the fifth scan lines GRL1 to GRLn.

The emission driver EDC may supply an emission signal to the emission lines ESL1 to ESLn based on a second control signal ECS. For example, the emission signal may be sequentially supplied to the emission lines ESL1 to ESLn.

Transistors connected to the emission lines ESL1 to ESLn of the disclosure may be configured as N-type transistors. At this time, the emission signal supplied to the emission lines ESL1 to ESLn may be set to a gate-off voltage. Transistors receiving an emission signal may be turned-off in case that the emission signal is supplied, and may be set to the state of being turned-on otherwise.

The second control signal ECS may include an emission start signal and clock signals, and the emission driver EDC may be implemented as a shift register which sequentially shifts the emission start signal in a pulse form using the clock signals so as to sequentially generate and output an emission signal in a pulse form.

The data driver DDC may receive a third control signal DCS and image data RGB from the timing controller TC. The data driver DDC may convert the image data RGB in a digital form into an analog data signal (i.e., a data signal). The data driver DDC may supply a data signal to the data lines DL1 to DLm in correspondence to the third control signal DCS.

The third control signal DCS may include a data enable signal, a horizontal start signal, a data clock signal, and the like, which indicate the output of a valid data signal. For example, the data driver DDC may include a shift register configured to shift a horizontal start signal in synchronization with a data clock signal to generate a sampling signal, a latch configured to latch the image data RGB in response to the sampling signal, a digital-to-analog converter (or, a decoder) configured to convert the latched image data (e.g., data in a digital form) into data signals in an analog form, and buffers (or, amplifiers) configured to output the data signals to the data lines DL1 to DLm.

The power supplier PWS may supply the first power voltage VDD, the second power voltage VSS, and the third power voltage VREF for driving the pixel PXij to the display panel DP. The power supplier PWS may supply at least one voltage of the fourth power voltage VINT1, the fifth power voltage VINT2, and the sixth power voltage VCOMP to the display panel DP.

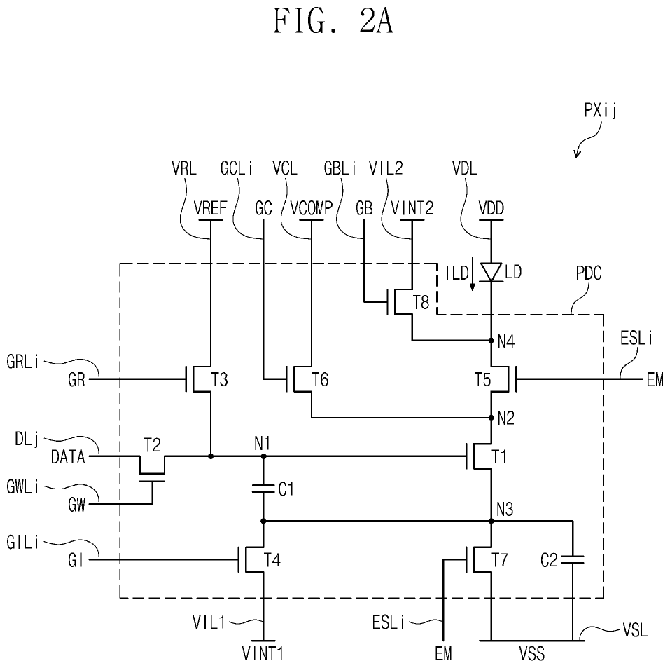

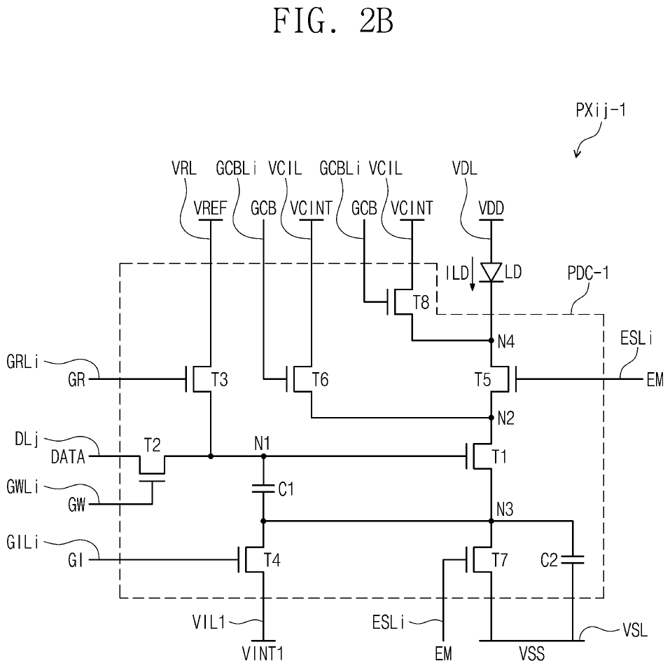

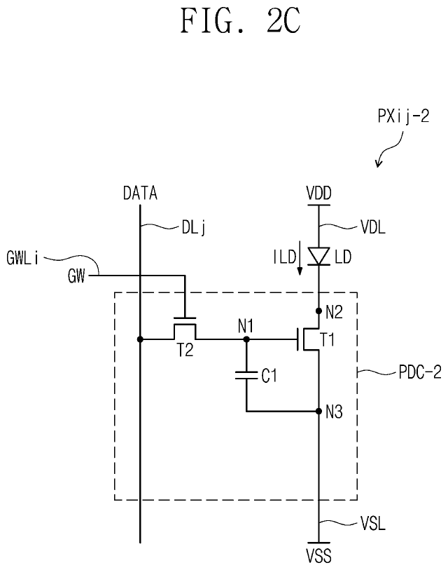

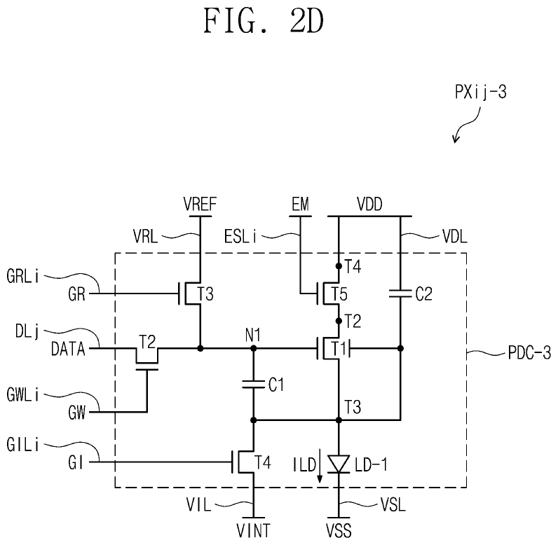

As an example, the power supplier PWS may respectively supply the first power voltage VDD, the second power voltage VSS, the third power voltage VREF, the fourth power voltage VINT1, the fifth power voltage VINT2, and the sixth power voltage VCOMP to the display panel DP via a first power line VDL (see FIG. 2A), a second power line VSL (see FIG. 2A), a third power line VRL (or a reference voltage line VRL, see FIG. 2A), a fourth power line VIL1 (or a first initialization voltage line VIL1, see FIG. 2A), a fifth power line VIL2 (or a second initialization voltage line VIL2, see FIG. 2A), and a sixth power line VCL (or a compensation voltage line VCL, see FIG. 2A), which are not illustrated.

The power supplier PWS may be implemented as a power management integrated circuit, but is not limited thereto.

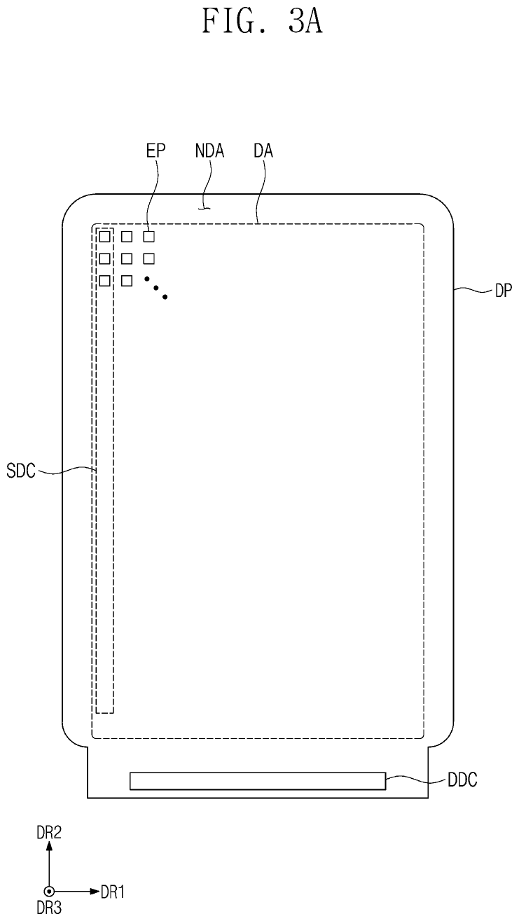

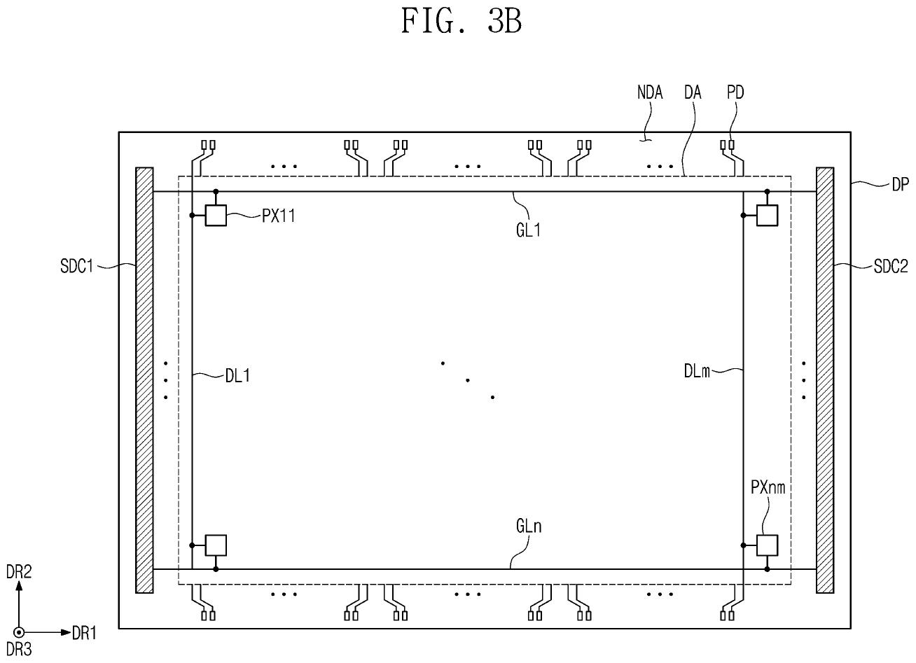

The timing controller TC may generate the first control signal SCS, the second control signal ECS, the third control signal DCS, and a fourth control signal PCS based on input image data IRGB, a synchronization signal Sync (e.g., a vertical synchronization signal, a horizontal synchronization signal, etc.), a data enable signal DE, a clock signal, etc. The first control signal SCS may be supplied to the scan driver SDC, the second control signal ECS may be supplied to the emission driver EDC, the third control signal DCS may be supplied to the data driver DDC, and the fourth control signal PCS may be supplied to the power supplier PWS. The timing controller TC may generate the image data RGB (or, frame data) by rearranging the input image data IRGB in correspondence to an arrangement of the pixels (e.g. pixels PX11 to PXnm shown in FIG. 3B) in the display panel DP.

The scan driver SDC, the emission driver EDC, the data driver DDC, the power supplier PWS, and/or the timing controller TC may be directly provided on the display panel DP, or may be provided in the form of a separate driving chip and be connected to the display panel DP. At least two among the scan driver SDC, the emission driver EDC, the data driver DDC, the power supplier PWS, and the timing controller TC may be provided as one driving chip. For example, the data driver DDC and the timing controller TC may be provided as one driving chip.

In the above, the display device DD according to an embodiment of the disclosure has been described with reference to FIG. 1, but the display device of the disclosure is not limited thereto. Signal lines may be further added or omitted depending on the configuration of a pixel. The connection relationship between one pixel and signal lines may be changed. In case that any one of the signal lines is omitted, another signal line may replace the omitted signal line, but embodiments of the disclosure are not limited thereto.

FIG. 2A to FIG. 2D are schematic diagrams of equivalent circuits of a pixel according to an embodiment of the disclosure. FIG. 2A to FIG. 2D illustrate equivalent circuit diagrams of pixels PXij, PXij-1, PXij-2 and PXij-3 connected to the i-th first scan line GWLi (hereinafter, a write scan line GWLi) and connected to the j-th data line DLj (hereinafter, a data line DLj).

As illustrated in FIG. 2A, the pixel PXij may include a light emitting element LD and a pixel driver PDC. The light emitting element LD may be connected to the first power line VDL and to the pixel driver PDC.

The pixel driver PDC may be connected to the scan lines GWLi, GCLi, GILi, GBLi, and GRLi, the data line DLj, the emission line ESLi, and the power voltage lines VDL, VSL, VIL1, VIL2, VRL, and VCL. The pixel driver PDC may include first to eighth transistors T1, T2, T3, T4, T5, T6, T7, and T8, a first capacitor C1, and a second capacitor C2. Hereinafter, a case in which each of the first to eighth transistors T1, T2, T3, T4, T5, T6, T7, and T8 is an N-type transistor will be described as an example. However, embodiments of the disclosure are not limited thereto, and some of the first to eighth transistors T1 to T8 may be N-type transistors, and the others may be P-type transistors, or each of the first to eighth transistors T1 to T8 may be a P-type transistor, but embodiments of the disclosure are not limited to any one embodiment.

A gate of the first transistor T1 may be connected to a first node N1. A first electrode of the first transistor T1 may be connected to a second node N2, and a second electrode thereof may be connected to a third node N3. The first transistor T1 may be a driving transistor. The first transistor T1 may control a driving current ILD flowing from the first power line VDL to the second power line VSL via the light emitting element LD in correspondence to a voltage of the first node N1. At this time, the first power voltage VDD may be set to a voltage having a potential higher than that of the second power voltage VSS.

In the disclosure, “being electrically connected between a transistor and a signal line or between a transistor and a transistor” means that “a source, a drain, or a gate of the transistor have a shape of a single body with the signal line, or transistors are connected through a connection electrode.” In addition, in the disclosure, the gate may be referred to as a gate electrode, the source may be referred to as a source electrode, and the drain may be referred to as a drain electrode.

The second transistor T2 may include a gate connected to the write scan line GWLi, a first electrode connected to the data line DLj, and a second electrode connected to the first node N1. The second transistor T2 may supply a data signal DATA to the first node N1 in response to the write scan signal GW transmitted through the write scan line GWLi. The second transistor T2 may be turned on in case that the write scan signal GW is supplied to the write scan line GWLi and electrically connect the data line DLj and the first node N1.

The third transistor T3 may be connected between the first node N1 and the reference voltage line VRL. A first electrode of the third transistor T3 may receive the reference voltage VREF through the reference voltage line VRL, and a second electrode of the third transistor T3 may be connected to the first node N1. In an embodiment, a gate of the third transistor T3 may receive a reset scan signal GR through the i-th fifth scan line GRLi (hereinafter, a reset scan line GRLi). The third transistor T3 may be turned on in case that the reset scan signal GR is supplied to the reset scan line GRLi and provide the reference voltage VREF to the first node N1.

The fourth transistor T4 may be connected between the third node N3 and the first initialization voltage line VIL1. A first electrode of the fourth transistor T4 may be connected to the third node N3, and a second electrode of the fourth transistor T4 may be connected to the first initialization voltage line VIL1 which provides the first initialization voltage VINT1. The fourth transistor T4 may be referred to as a first initialization transistor. A gate of the fourth transistor T4 may receive a first initialization scan signal GI through the i-th third scan line GILi (hereinafter, a first initialization scan line GILi). The fourth transistor T4 may be turned on in case that the first initialization scan signal GI is supplied to the first initialization scan line GILi and supply the first initialization voltage VINT1 to the third node N3.

The fifth transistor T5 may be connected between the first transistor T1 and the light emitting element LD. Specifically, a gate of the fifth transistor T5 may receive an emission signal EM through the i-th emission line ESLi (hereinafter, an emission line ESLi). A first electrode of the fifth transistor T5 may be connected to a cathode of the light emitting element LD through a fourth node N4, and a second electrode of the fifth transistor T5 may be connected to the first electrode of the first transistor T1 through the second node N2. The fifth transistor T5 may be referred to as a first emission control transistor. The fifth transistor T5 may be turned on in case that the emission signal EM is supplied to the emission line ESLi, and electrically connect the light emitting element LD and the first transistor T1.

The sixth transistor T6 may be connected between the compensation voltage line VCL and the second node N2. A first electrode of the sixth transistor T6 may receive the compensation voltage VCOMP through the compensation voltage line VCL, and a second electrode of the sixth transistor T6 may be connected to the second node N2 and be electrically connected to the first electrode of the first transistor T1. A gate of the sixth transistor T6 may receive a compensation scan signal GC through the i-th second scan line GCLi (hereinafter, a compensation scan line GCLi). The sixth transistor T6 may be turned on in case that the compensation scan signal GC is supplied to the compensation scan line GCLi and provide the compensation voltage VCOMP to the second node N2, and during a compensation period, a threshold voltage of the first transistor T1 may be compensated.

The seventh transistor T7 may be connected between the second power line VSL and the third node N3. A first electrode of the seventh transistor T7 may be connected to the second electrode of the first transistor T1 through the third node N3, and a second electrode of the seventh transistor T7 may receive the second power voltage VSS through the second power line VSL. A gate of the seventh transistor T7 may be electrically connected to the emission line ESLi. The seventh transistor T7 may be referred to as a second emission control transistor. The seventh transistor T7 may be turned on in case that the emission signal EM is supplied to the emission line ESLi, and electrically connect the second electrode of the first transistor T1 and the second power line VSL.

In an embodiment, the fifth transistor T5 and the seventh transistor T7 are illustrated as being connected to the same emission line ESLi and turned on through the same emission signal EM, but this is only an example, and the fifth transistor T5 and the seventh transistor T7 may be independently turned on by different signals distinguished from each other. In the pixel driver PDC according to an embodiment of the disclosure, any one of the fifth transistor T5 and the seventh transistor T7 may be omitted.

The eighth transistor T8 may be connected between the second initialization voltage line VIL2 and the fourth node N4. That is, the eighth transistor T8 may include a gate connected to the i-th fourth scan line GBLi (hereinafter, a second initialization scan line GBLi), a first electrode connected to the second initialization voltage line VIL2, and a second electrode connected to the fourth node N4. The eighth transistor T8 may be referred to as a second initialization transistor. The eighth transistor T8 may supply the second initialization voltage VINT2 to the fourth node N4 corresponding to the cathode of the light emitting element LD in response to a second initialization scan signal GB transmitted through the second initialization scan line GBLi. The cathode of the light emitting element LD may be initialized by the second initialization voltage VINT2.

The first capacitor C1 may be disposed between the first node N1 and the third node N3. The first capacitor C1 may store a difference voltage between the first node N1 and the third node N3. The first capacitor C1 may be referred to as a storage capacitor.

The second capacitor C2 may be disposed between the third node N3 and the second power line VSL. For example, one electrode of the second capacitor C2 may be connected to the second power line VSL which is supplied with the second power voltage VSS, and the other electrode of the second capacitor C2 may be connected to the third node N3. The second capacitor C2 may store a charge corresponding to a voltage difference between the second power voltage VSS and the third node N3. The second capacitor C2 may be referred to as a hold capacitor. The second capacitor C2 may have a higher storage capacity than the first capacitor C1. Accordingly, the second capacitor C2 may minimize a voltage change of the third node N3 in correspondence to a voltage change of the first node N1.

In an embodiment, the light emitting element LD may be connected to the pixel driver PDC through the fourth node N4. The light emitting element LD may include an anode connected to the first power line VDL and a cathode opposing the anode. In an embodiment, the light emitting element LD may be connected to the pixel driver PDC through the cathode. For example, in the pixel PXij according to the disclosure, a connection node to which the light emitting element LD and the pixel driver PDC are connected may be the fourth node N4, and the fourth node N4 may correspond to a connection node between the first electrode of the fifth transistor T5 and the cathode of the light emitting element LD. Accordingly, the potential of the fourth node N4 may substantially correspond to the potential of the cathode of the light emitting element LD.

Specifically, the anode of the light emitting element LD may be connected to the first power line VDL and be applied with the first power voltage VDD, which is a constant voltage, and the cathode thereof may be connected to the first transistor T1 though the fifth transistor T5. For example, in an embodiment in which the first to eighth transistors T1 to T8 are N-type transistors, the potential of the third node N3 corresponding to a source of the first transistor T1, which is a driving transistor, may not be directly affected by the characteristics of the light emitting element LD. Therefore, even if the light emitting element LD is deteriorated, the influence on transistors constituting the pixel driver PDC, particularly a gate-source voltage Vgs of a driving transistor, may be reduced. For example, since an amount of change in a driving current due to the deterioration of the light emitting element LD may be reduced, an afterimage defect of the display panel due to an increase in usage time may be reduced and the lifespan thereof may be improved.

Each of the first to eighth transistors T1 to T8 may be an N-type transistor. Accordingly, a coupling effect may occur between the gate of the first transistor T1 and the second electrode thereof. Specifically, in response to a voltage change of the second electrode of the first transistor T1, that is, the third node N3, the gate of the first transistor T1, that is, the first node N1 may be connected to cause a corresponding voltage change in the first node N1. The voltage change of the first node N1 may determine a current flowing in the light emitting elements LD and LD-1. According to the disclosure, a shielding electrode may be disposed between the first node N1 and the light emitting elements LD and LD-1. Accordingly, by preventing the electrical influence of other components on the first node N1, it may be possible to prevent the voltage change of the first node N1 from being affected by other effects other than the first capacitor C1, for example, a capacitance between the gate of the first transistor T1 and anodes of the light emitting elements LD and LD-1. Accordingly, it may be possible to prevent the occurrence of luminance differences due to a difference in capacitance between light emitting portions, and prevent the occurrence of display defects such as a moire phenomenon.

In an embodiment, some of the second to eighth transistors T2, T3, T4, T5, T6, T7, and T8 may be simultaneously turned on through the same scan signal. FIG. 2B illustrates an embodiment in which the sixth transistor T6 and the eighth transistor T8 are simultaneously turned on through the same scan signal. As illustrated in FIG. 2B, in a pixel driver PDC-1 constituting the pixel PXij-1, the eighth transistor T8 and the sixth transistor T6 may be connected to one i-th scan line GCBLi (hereinafter, a compensation initialization scan line GCBLi). Accordingly, the eighth transistor T8 and the sixth transistor T6 may be operated by the same scan signal GCB (hereinafter, a compensation initialization scan signal GCB). The eighth transistor T8 and the sixth transistor T6 may be simultaneously turned on/off by the compensation initialization scan signal GCB. The compensation initialization scan line GCBLi may substantially correspond to the compensation scan line GCLi and the second initialization scan line GBLi illustrated in FIG. 2A which are each provided as a single scan line. Accordingly, initializing the cathode of the light emitting element LD and compensating the threshold voltage of the first transistor T1 may be performed at the same timing.

In an embodiment, the eighth transistor T8 and the sixth transistor T6 may be connected to one power line VCIL (hereinafter, a compensation initialization voltage line VCIL). For example, the eighth transistor T8 and the sixth transistor T6 may transmit the same power voltage VCINT. The compensation initialization voltage line VCIL may substantially correspond to the compensation voltage line VCL and the second initialization voltage line VIL2 illustrated in FIG. 2A which are each provided as a single power voltage line. Accordingly, the initialization of the cathode of the light emitting element LD and the compensation of the threshold voltage of the first transistor T1 may be achieved with the application of the same power voltage. Since the initialization operation of a cathode and the compensation operation of a driving transistor may be performed with one power voltage, the design of a pixel driver may be simplified. This is only an example, and embodiments of the disclosure are not limited to any one embodiment.

In other embodiments, as illustrated in FIG. 2C, the pixel PXij-2 may include a pixel driver PDC-2 including two transistors T1 and T2 and one capacitor C1. The pixel driver PDC-2 may be connected to a light emitting element LD, a write scan line GWLi, a data line DLj, and a second power line VSL. The pixel driver PDC-2 illustrated in FIG. 2C may correspond to the pixel driver PDC illustrated in FIG. 2A from which the third to eighth transistors T3 to T8 and the second capacitor C2 are omitted.

The first transistor T1 may include a gate connected to a first node N1, a first electrode connected to a second node N2, and a second electrode connected to a third node N3. The second node N2 may be a node connected to the side of a first power line VDL, and the third node N3 may be a node connected to the side of a second power line VSL. The first transistor T1 may be connected to the light emitting element LD through the second node N2 and may be connected to the second power line VSL through the third node N3. The first transistor T1 may be a driving transistor.

The second transistor T2 may include a gate for receiving a write scan signal GW through the write scan line GWLi, a first electrode connected to the data line DLj, and a second electrode connected to the first node N1. The second transistor T2 may supply a data signal DATA to the first node N1 in response to the write scan signal GW transmitted through the write scan line GWLi.

The first capacitor C1 may include an electrode connected to the first node N1 and an electrode connected to the third node N3. The first capacitor C1 may store the data signal DATA transmitted to the first node N1.

The light emitting element LD may include an anode and a cathode. In an embodiment, the anode of the light emitting element LD may be connected to the first power line VDL, and the cathode thereof may be connected to the pixel driver PDC-2 through the second node N2. In an embodiment, the cathode of the light emitting element LD may be connected to the first transistor T1. The light emitting element LD may emit light in correspondence to an amount of a current flowing in the first transistor T1 of the pixel driver PDC-2.

In an embodiment in which the first and second transistors T1 and T2 are N-type transistors, the second node N2 to which the cathode of the light emitting element LD and the pixel driver PDC-2 are connected may correspond to a drain of the first transistor T1. For example, a change in a gate-source voltage Vgs of the first transistor T1 due to the light emitting element LD may be prevented. Accordingly, since an amount of change in a driving current due to the deterioration of the light emitting element LD may be reduced, an afterimage defect of a display panel due to an increase in usage time may be reduced and the lifespan thereof may be improved.

In other embodiments, as illustrated in FIG. 2D, a pixel PXij-3 may include the light emitting element LD-1 and a pixel driver PDC-3 connected to an anode of the light emitting element LD-1. FIG. 2D illustrates the pixel driver PDC-3 including five transistors T1, T2, T3, T4, and T5 and two capacitors C1 and C2. The pixel driver PDC-3 may be connected to a light emitting element LD-1, a data line DLj, a write scan line GWLi, a first initialization scan line GILi, a reset scan line GRLi, an emission line ESLi, an initialization voltage line VIL, a reference voltage line VRL, and a first power line VDL. The initialization voltage line VIL may correspond to the first initialization voltage line VIL1 illustrated in FIG. 2A.

The pixel driver PDC-3 illustrated in FIG. 2D may correspond to one composed of the first to fifth transistors T1 to T5 among the first to eighth transistors T1 to T8 illustrated in FIG. 2A. For example, the first transistor T1 of the pixel driver PDC-3 may include a gate connected to a first node N1, a first electrode connected to a second node N2, and a second electrode connected to a third node N3. The second transistor T2 of the pixel driver PDC-3 may include a gate connected to the write scan line GWLi, a first electrode connected to the data line DLj, and a second electrode connected to the first node N1. The third transistor T3 of the pixel driver PDC-3 may include a gate connected to the reset scan line GRLi, a first electrode connected to the reference voltage line VRL, and a second electrode connected to the first node N1. The fourth transistor T4 of the pixel driver PDC-3 may include a gate connected to the first initialization scan line GILi, a first electrode connected to the third node N3, and a second electrode connected to the initialization voltage line VIL. The fifth transistor T5 of the pixel driver PDC-3 may include a gate connected to the emission line ESLi, a first electrode connected to a fourth node N4, and a second electrode connected to the second node N2.

A first capacitor C1 of the pixel driver PDC-3 may correspond to the first capacitor C1 illustrated in FIG. 2A. For example, the first capacitor C1 of the pixel driver PDC-3 may include one electrode connected to the first node N1 and the other electrode connected to the third node N3.

A second capacitor C2 of the pixel driver PDC-3 may be disposed between the third node N3 and the first power line VDL. For example, one electrode of the second capacitor C2 may be connected to the first power line VDL which is supplied with a first power voltage VDD, and the other electrode of the second capacitor C2 may be connected to the third node N3. The second capacitor C2 may store a charge corresponding to a voltage difference between the first power voltage VDD and the third node N3. The second capacitor C2 may have a higher storage capacity than the first capacitor C1. Accordingly, the second capacitor C2 may minimize a voltage change of the third node N3 in correspondence to a voltage change of the first node N1.

The first transistor T1 of the pixel driver PDC-3 according to an embodiment may further include a lower gate. The lower gate may be connected to the other electrode of the second capacitor C2 to be connected to the third node N3. This is only an example, and in the pixel driver PDC-3 according to an embodiment of the disclosure, the first transistor T1 may have a single gate structure, and is not limited to any one embodiment.

The pixel driver PDC-3 may be connected to the light emitting element LD-1 through the third node N3. For example, the third node N3 may be a node to which the second electrode of the first transistor T1, the first electrode of the fourth transistor T4, the other electrode of the second capacitor C2, and the anode of the light emitting element LD are connected. The light emitting element LD-1 illustrated in FIG. 2D may include the anode connected to the pixel driver PDC-3 and a cathode connected to a second power line VSL. The light emitting element LD-1 may emit light in correspondence to an amount of a current flowing in the first transistor T1 of the pixel driver PDC-3.

FIG. 2A to FIG. 2D illustrate circuits for the pixel drivers PDC, PDC-1, PDC-2, and PDC-3 according to an embodiment of the disclosure, and as long as it is a circuit connected to the light emitting elements LD and LD-1 in a display panel according to an embodiment of the disclosure, the number or disposition relationship of transistors, and the number or disposition relationship of capacitors may be designed in various ways, and are not limited to any one embodiment.

FIG. 3A and FIG. 3B are schematic plan views illustrating a display panel according to an embodiment of the disclosure. In each of FIG. 3A and FIG. 3B, some components are omitted. Hereinafter, the disclosure will be described with reference to FIG. 3A and FIG. 3B. Referring to FIG. 3A, a display panel DP of an embodiment may be divided into a display region DA and a peripheral region NDA (or a non-display region NDA). The display region DA may include multiple light emitting portions EP.

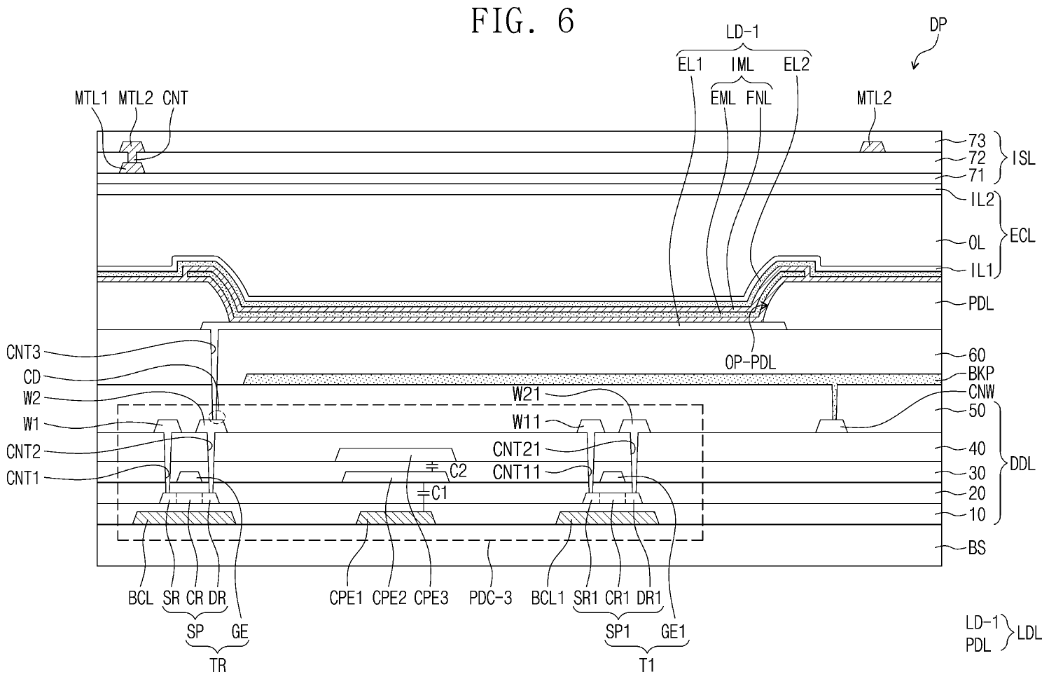

The light emitting portions EP may be regions each emitting light by the pixels PXij (see FIG. 1). Specifically, each of the light emitting portions EP may correspond to a light emitting opening OP-PDL (see FIG. 6) to be described later.

The peripheral region NDA may be disposed adjacent to the display region DA. In an embodiment, the peripheral region NDA is illustrated as having a shape surrounding the display region DA. However, this is only an example, and the peripheral region NDA may be disposed on, e.g., a side of the display region DA, or may be omitted, and is not limited to any one embodiment.

In an embodiment, a scan driver SDC and a data driver DDC may be mounted on the display panel DP. In an embodiment, the scan driver SDC may be disposed in the display region DA, and the data driver DDC may be disposed in the peripheral region NDA. The scan driver SDC may overlap at least some of the light emitting portions EP disposed in the display region DA in a plan view. Since the scan driver SDC may be disposed in the display region DA, the area of the peripheral region NDA may be reduced as compared to a typical display panel in which a scan driver is disposed in a peripheral region, and a display device with a thin bezel may be readily implemented.

Unlike what is illustrated in FIG. 3A, the scan driver SDC may be provided as two portions separated from each other. The two scan drivers SDC may be disposed spaced apart from each other left and right with the center of the display region DA interposed therebetween. In other embodiments, two or more scan drivers SDC may be provided, and is not limited to any one embodiment.

FIG. 3A illustrates an example of a display panel, and a data driver DDC may be disposed in the display region DA. At this time, some of the light emitting portions EP disposed in the display region DA may overlap the data driver DDC in a plan view.

In an embodiment, the data driver DDC may be provided in the form of a separate driving chip independent from the display panel DP and be connected to the display panel DP. However, this is only an example, and the data driver DDC may be provided in the same process with the scan driver SDC so as to constitute the display panel DP, and is not limited to any one embodiment.

As illustrated in FIG. 3B, the display panel DP may have a shape in which a length corresponding to a first direction DR1 is longer than a length corresponding to a second direction DR2. In an embodiment, the display panel DP may include multiple scan drivers SDC1 and SDC2. The scan drivers SDC1 and SDC2 are illustrated as including a first scan driver SDC1 and a second scan driver SDC2 disposed spaced apart from each other in the first direction DR1.

The first scan driver SDC1 may be connected to some of scan lines GL1 to GLn, and the second scan driver SDC2 may be connected to others of the scan lines GL1 to GLn. For example, the first scan driver SDC1 may be connected to odd-numbered scan lines among the scan lines GL1 to GLn, and the second scan driver SDC2 may be connected to even-numbered scan lines among the scan lines GL1 to GLn.

For case of description, FIG. 3B illustrates pads PD of data lines DL1 to DLm. The pads PD may be defined at ends of the data lines DL1 to DLm. The data lines DL1 to DLm may be connected to the data driver DDC (see FIG. 3A) through the pads PD.

According to the disclosure, the pads PD may be divided and arranged at positions spaced apart from each other with the display region DA interposed therebetween in the peripheral region NDA. For example, some of the pads PD may be disposed on an upper side, that is, a side adjacent to the first scan line GL1 among the scan lines GL1 to GLn, and others of the pads PD may be disposed on a lower side, that is, a side adjacent to the last scan line GLn among the scan lines GL1 to GLn. In an embodiment, pads PD connected to odd-numbered data lines among the data lines DL1 to DLm may be disposed on the upper side, and pads PD connected to even-numbered data lines among the data lines DL1 to DLm may be disposed on the lower side.

Although not illustrated, the display panel DP may include multiple upper data drivers connected to the pads PD disposed on the upper side and/or multiple lower data drivers connected to the pads PD disposed on the lower side. However, this is only an example, and the display panel DP may include one upper data driver connected to the pads PD disposed on the upper side and/or one lower data driver connected to the pads PD disposed on the lower side. For example, the pads PD according to an embodiment of the disclosure may be disposed on only one side of the display panel DP and be connected to a single data driver, and is not limited any one embodiment.

As described above with reference to FIG. 3A, even in the display panel DP in FIG. 3B, a scan driver and/or a data driver may be disposed in the display region DA, and accordingly, some of the light emitting portions disposed in the display regions DA may overlap the scan driver and/or the data driver in a plan view.

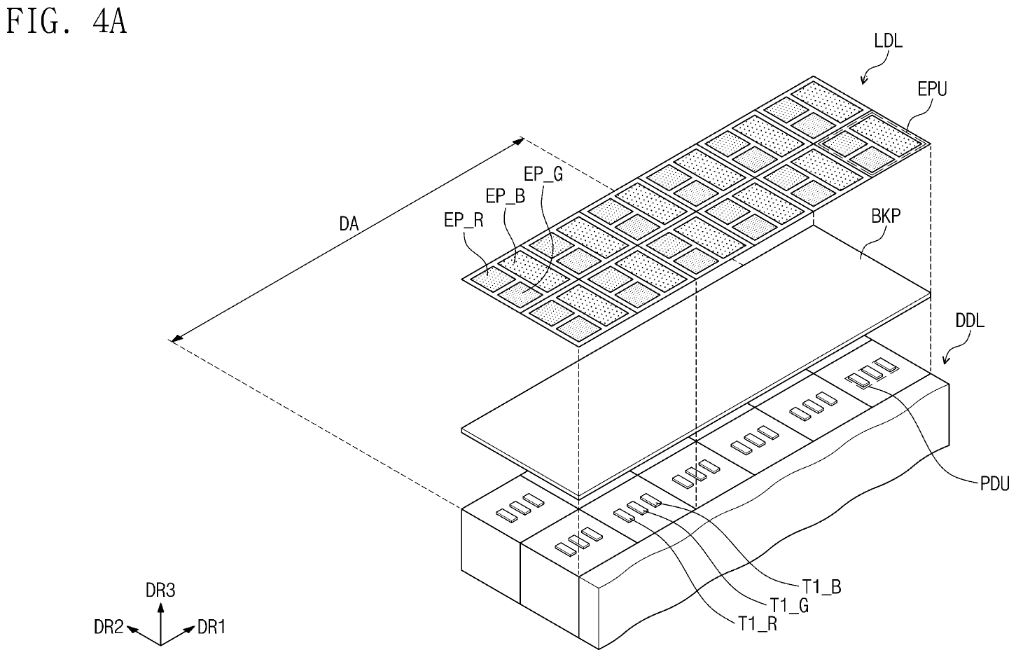

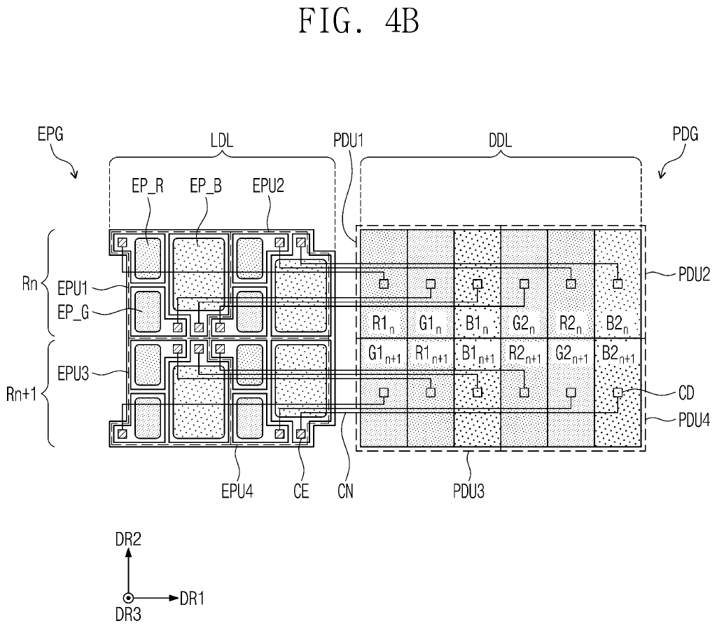

FIG. 4A and FIG. 4B are schematic views illustrating a display panel according to an embodiment of the disclosure. FIG. 4A is a perspective view schematically illustrating the display region DA, and FIG. 4B is a plan view schematically illustrating a portion of the display panel. Referring to FIG. 4A and FIG. 4B, a display panel DP may include a driving element layer DDL, a light emitting element layer LDL, and a blocking pattern BKP.

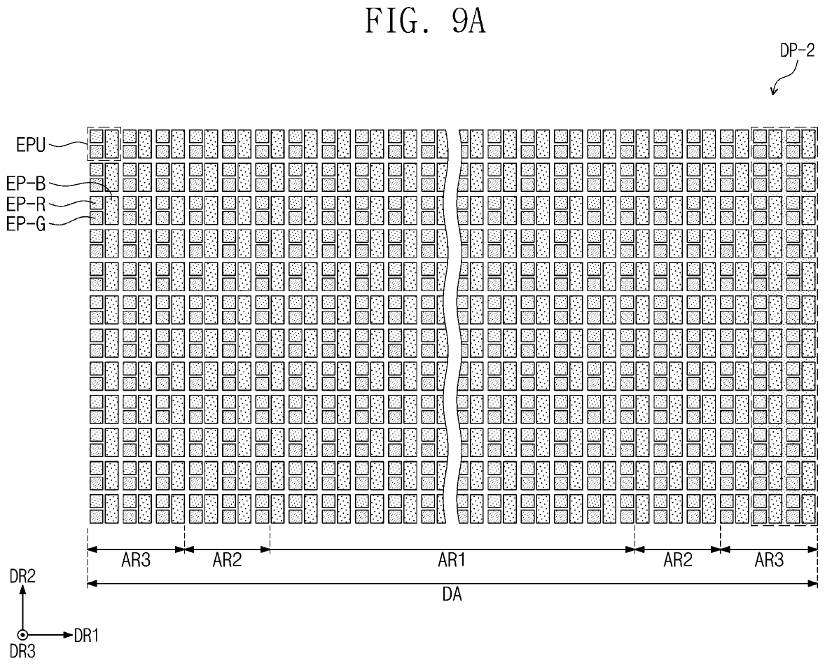

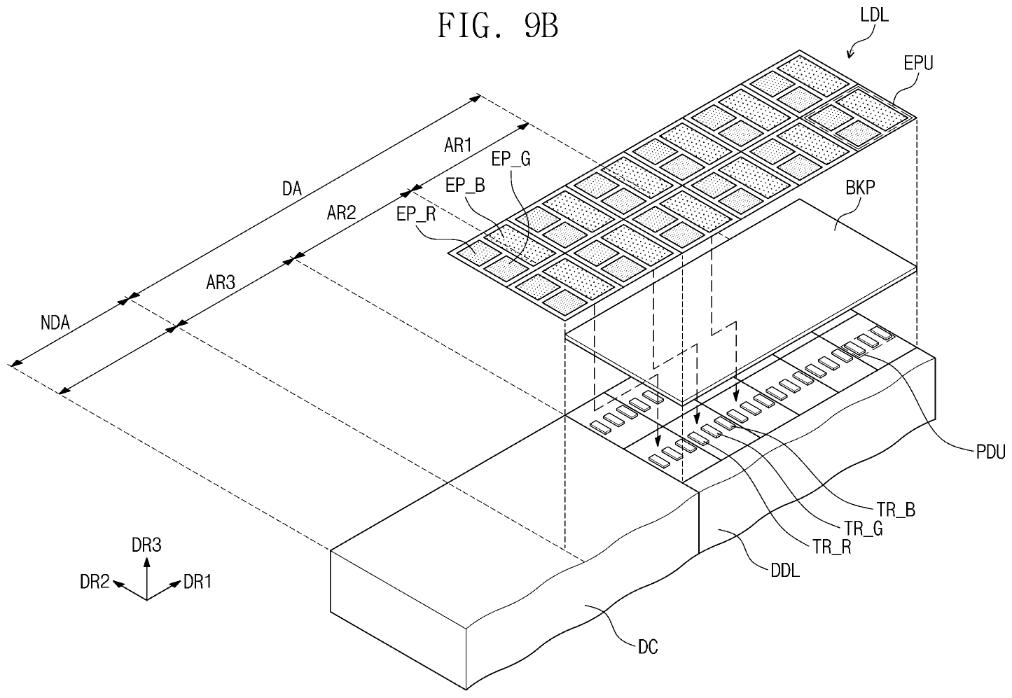

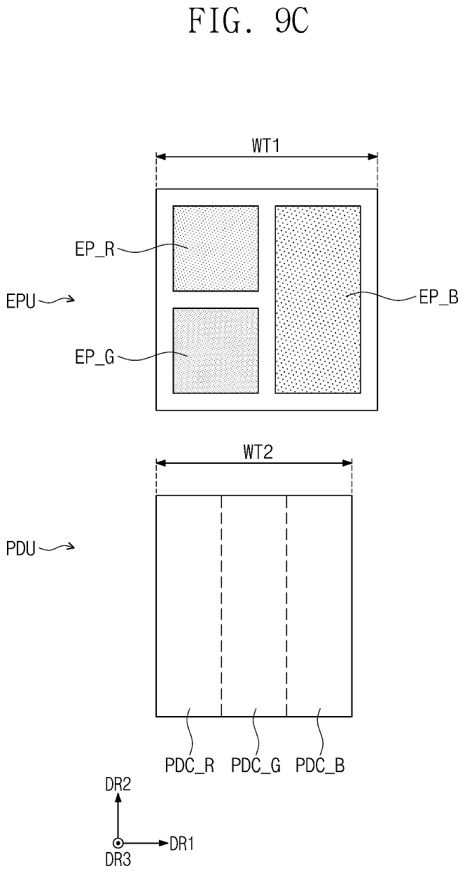

The driving element layer DDL may include multiple pixel driving units PDU (e.g. pixel driving units PDU1 to PDU4 shown in FIG. 4B). Each of the pixel driving units PDU may include at least one pixel driver PDC. In an embodiment, one pixel driving unit PDU is illustrated as including three pixel drivers PDC_R, PDC_G, and PDC_B (e.g. refer to FIG. 9C) arranged along (in) the first direction DR1. For case of description, FIG. 4A and FIG. 4B each illustrate first transistors T1_R, T1_G, and T1_B respectively constituting the pixel drivers PDC_R, PDC_G, and PDC_B, and other components respectively constituting a pixel drivers PDC_R, PDC_G, and PDC_B are omitted.

The light emitting element layer LDL may include multiple light emitting units EPU. Each of the light emitting units EPU may include at least one light emitting portion. One light emitting portion may correspond to one light emitting element LD (see FIG. 2A). In an embodiment, one light emitting unit EPU is illustrated as including three light emitting portions EP_R, EP_G, and EP_B.

The three light emitting portions EP_R, EP_G, and EP_B may be each connected to a corresponding one among the three pixel drivers PDC_R, PDC_G, and PDC_B. An emission connection part CE may be defined in each of the light emitting portions EP_R, EP_G, and EP_B, and a driver connection part CD may be defined in each of the pixel drivers PDC_R, PDC_G, and PDC_B. Since the emission connection part CE and the driver connection part CD which correspond to each other are electrically connected, one light emitting unit EPU and a corresponding pixel driving unit PDU may be connected to each other.

In an embodiment, the arrangement form of the light emitting portions EP_R, EP_G, and EP_B constituting one light emitting unit EPU may be different from the arrangement form of the pixel drivers PDC_R, PDC_G, and PDC_B connected thereto. However, this is only an example, and the arrangement form of the light emitting portions EP_R, EP_G, and EP_B and the arrangement form of the pixel drivers PDC_R, PDC_G, and PDC_B may be the same as each other, or may be different from the form illustrated in FIG. 4A and FIG. 4B, and are not limited to any one embodiment.

FIG. 4B illustrates a portion of the light emitting element layer LDL and a portion of the driving element layer DDL which are spaced apart from each other in a plan view. FIG. 4B schematically illustrates a light emitting group EPG including two rows Rn and Rn+1 (hereinafter, a first row Rn, and a second row Rn+1) and a pixel driving group PDG connected to the light emitting group EPG. For case of description, some components are omitted. Hereinafter, referring to FIG. 4B, the light emitting element layer LDL and the driving element layer DDL will be described in more detail.

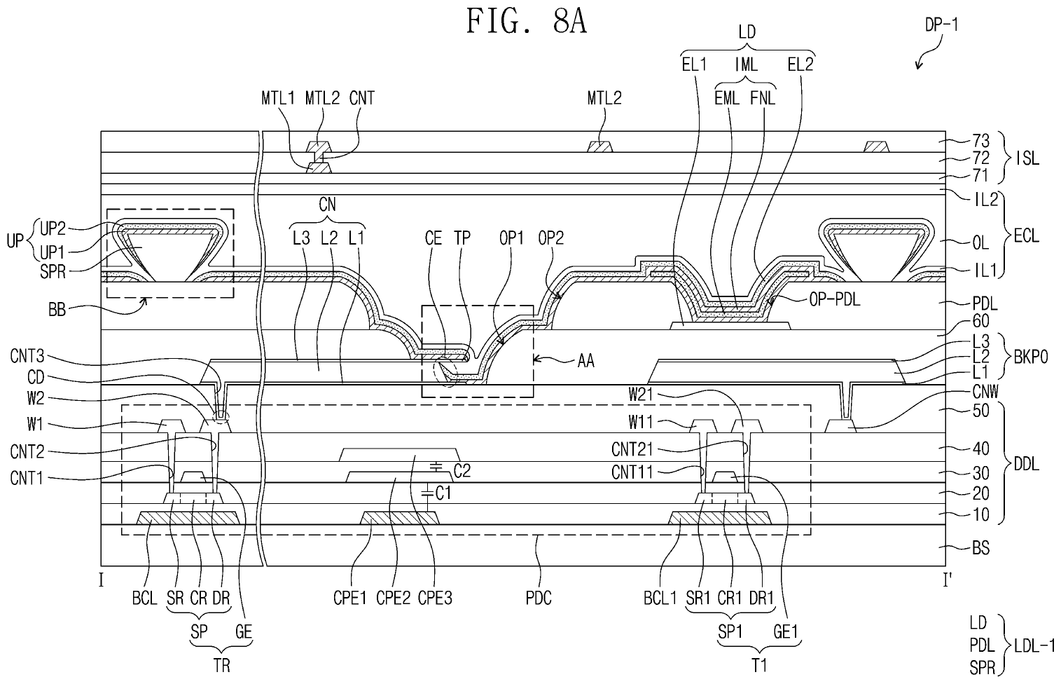

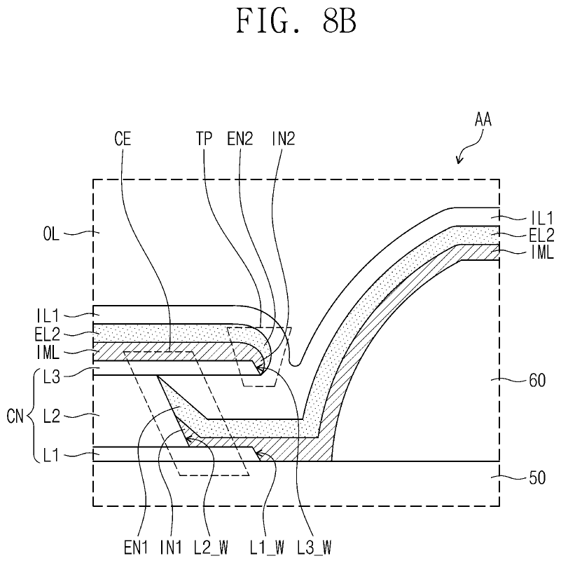

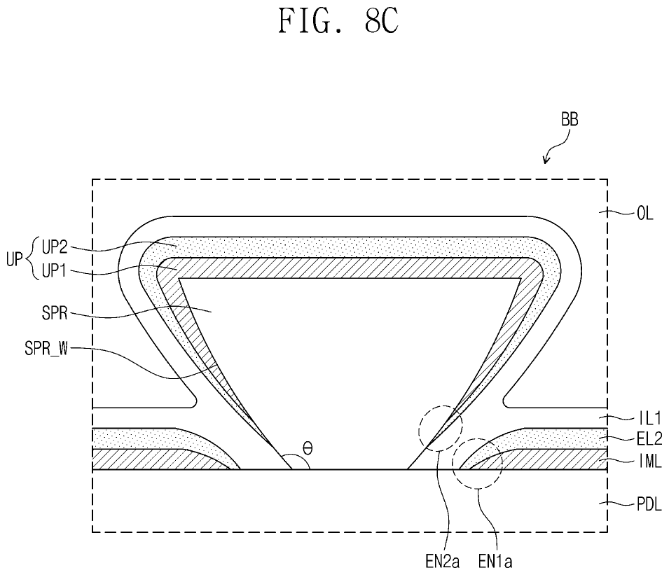

As illustrated in FIG. 4B, the light emitting group EPG may include a first light emitting unit EPU1 and a second light emitting unit EPU2 constituting the first row Rn, and a third light emitting unit EPU3 and a fourth light emitting unit EPU4 constituting the second row Rn+1. Each of the first to fourth light emitting units EPU1 to EPU4 may include first to third light emitting portions EP_R, EP_G, and EP_B, and is illustrated with different shades for distinction. As illustrated in FIG. 8A, each of the light emitting portions EP_R, EP_G, and EP_B may include a second electrode EL2 separated by a separator SPR.

Each of the first to fourth light emitting units EPU1 to EPU4 may include light emitting portions disposed not overlapping the pixel driving group PDG in a plan view.

The pixel driving group PDG may include pixel drivers R1ₙ, G1ₙ, B1ₙ, G2ₙ, R2ₙ, B2ₙ, G1ₙ₊₁, R1ₙ₊₁, B1ₙ₊₁, R2ₙ₊₁, G2ₙ₊₁, and B2ₙ₊₁ connected to light emitting portions constituting the first to fourth light emitting units EPU1 to EPU4. For case of description, the pixel drivers R1ₙ, G1ₙ, B1ₙ, G2ₙ, R2ₙ, B2ₙ, G1ₙ₊₁, R1ₙ₊₁, B1ₙ₊₁, R2ₙ₊₁, G2ₙ₊₁, and B2ₙ₊₁ are illustrated with shades corresponding to light emitting portions connected thereto, and are illustrated in quadrangular shapes.

Light emitting portions of the light emitting group EPG may be respectively connected to corresponding pixel drivers of the pixel driving group PDG. The connection between the light emitting portions of the light emitting group EPG and the corresponding pixel drivers may be achieved through the emission connection part CE and the driver connection part CD. The emission connection part CE may be defined in each of the light emitting portions EP_R, EP_G, and EP_B, and the driver connection part CD may be defined in each of the pixel drivers R1ₙ, G1ₙ, B1ₙ, G2ₙ, R2ₙ, B2ₙ, G1ₙ₊₁, R1ₙ₊₁, B1ₙ₊₁, R2ₙ₊₁, G2ₙ₊₁, and B2_{n+1.}

The emission connection part CE may be defined in a light emitting element of each of the light emitting portions EP_R, EP_G, and EP_B. Specifically, in case that each of the light emitting portions EP_R, EP_G, and EP_B includes the light emitting element LD illustrated in FIG. 2A or FIG. 2B, the emission connection part CE may be defined in the cathode of the light emitting element LD. In other embodiments, in case that each of the light emitting portions EP_R, EP_G, and EP_B includes the light emitting element LD-1 illustrated in FIG. 2D, the emission connection part CE may be defined in the anode of the light emitting element LD-1. The emission connection part CE may be defined in various configurations as long as it may be connected to a pixel driver, and is not limited to any one embodiment.

The driver connection part CD may be defined in a transistor of each of the pixel drivers R1ₙ, G1ₙ, B1ₙ, G2ₙ, R2ₙ, B2ₙ, G1ₙ₊₁, R1ₙ₊₁, B1ₙ₊₁, R2ₙ₊₁, G2ₙ₊₁, and B2ₙ₊₁. Specifically, in case that each of the pixel drivers R1ₙ, G1ₙ, B1ₙ, G2ₙ, R2ₙ, B2ₙ, G1ₙ₊₁, R1ₙ₊₁, B1ₙ₊₁, R2ₙ₊₁, G2ₙ₊₁, and B2ₙ₊₁ includes the pixel driver PDC illustrated in FIG. 2A, the drive connection part CD may be defined in the first electrode of the fifth transistor T5 or the second electrode of the eighth transistor T8. In other embodiments, in case that each of the pixel drivers R1ₙ, G1ₙ, B1ₙ, G2ₙ, R2ₙ, B2ₙ, G1ₙ₊₁, R1ₙ₊₁, B1ₙ₊₁, R2ₙ₊₁, G2ₙ₊₁, and B2ₙ₊₁ includes the pixel driver PDC-2 illustrated in FIG. 2C, the drive connection part CD may be defined in the first electrode of the first transistor T1. In other embodiments, in case that each of the pixel drivers R1ₙ, G1ₙ, B1ₙ, G2ₙ, R2ₙ, B2ₙ, G1ₙ₊₁, R1ₙ₊₁, B1ₙ₊₁, R2ₙ₊₁, G2ₙ₊₁, and B2ₙ₊₁ includes the pixel driver PDC-3 illustrated in FIG. 2D, the drive connection part CD may be defined in the second electrode of the first transistor T1 or the first electrode of the fourth transistor T4. The driver connection part CD may be defined in various configurations as long as it may be connected to a light emitting portion, and is not limited to any one embodiment.

The emission connection part CE may become one end of a connection between a light emitting portion and a pixel driver, and the driver connection part CD may become the other end of the connection between the light emitting portion and the pixel driver. For example, in case that the connection between the light emitting portion and the pixel driver is achieved through a predetermined or selected connection wire CN, the emission connection part CE may become one end of the connection wire CN and the driver connection part CD may become the other end of the connection wire CN. At this time, the emission connection part CE and the driver connection part CD may be respectively defined at positions spaced apart in a plan view.

In other embodiments, for example, in case that the connection between the light emitting portion and the pixel driver is achieved through a predetermined or selected contact-hole, the emission connection part CE may become an upper end of the contact-hole and the driver connection part CD (e.g. refer to FIG. 6) may become a lower end of the contact-hole. At this time, the emission connection part CE and the driver connection part CD may be respectively defined at positions overlapping in a plan view.

Referring back to FIG. 4A, the blocking pattern BKP may be disposed between the driving element layer DDL and the light emitting element layer LDL on a cross-section. The blocking pattern BKP may be a conductive pattern. Specifically, the blocking pattern BKP may be disposed between gates (not shown) of the first transistors T1_R, T1_G, and T1_B and anodes (not shown) of the light emitting portions EP_R, EP_G, and EP_B on a cross-section.

The blocking pattern BKP may overlap a gate of a first transistor in a plan view. In an embodiment, the blocking pattern BKP is illustrated in the form of being integrally formed and overlapping the first transistors T1_R, T1_G, and T1_B in a plan view, but this is only an example, and the blocking pattern BKP may be multiple patterns overlapping each of the first transistors T1_R, T1_G, and T1_B, or may be in the form of partially overlapping only some of the first transistors T1_R, T1_G, and T1_B. The blocking pattern BKP may have various shapes as long as it overlaps at least one first transistor, particularly a gate of a first transistor, in a plan view, and is not limited to any one embodiment.

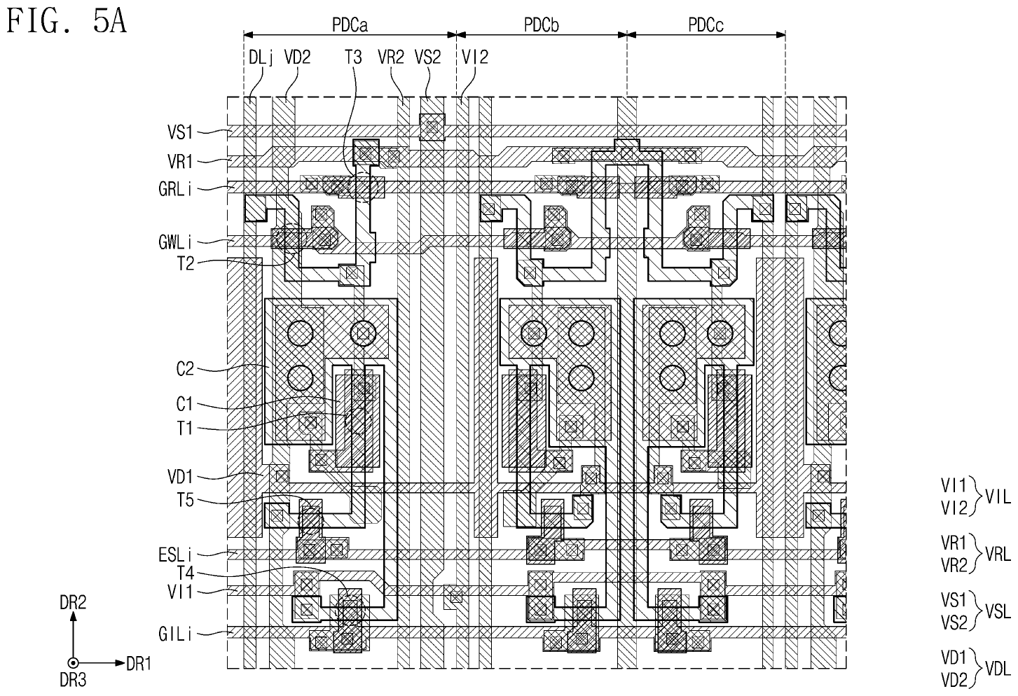

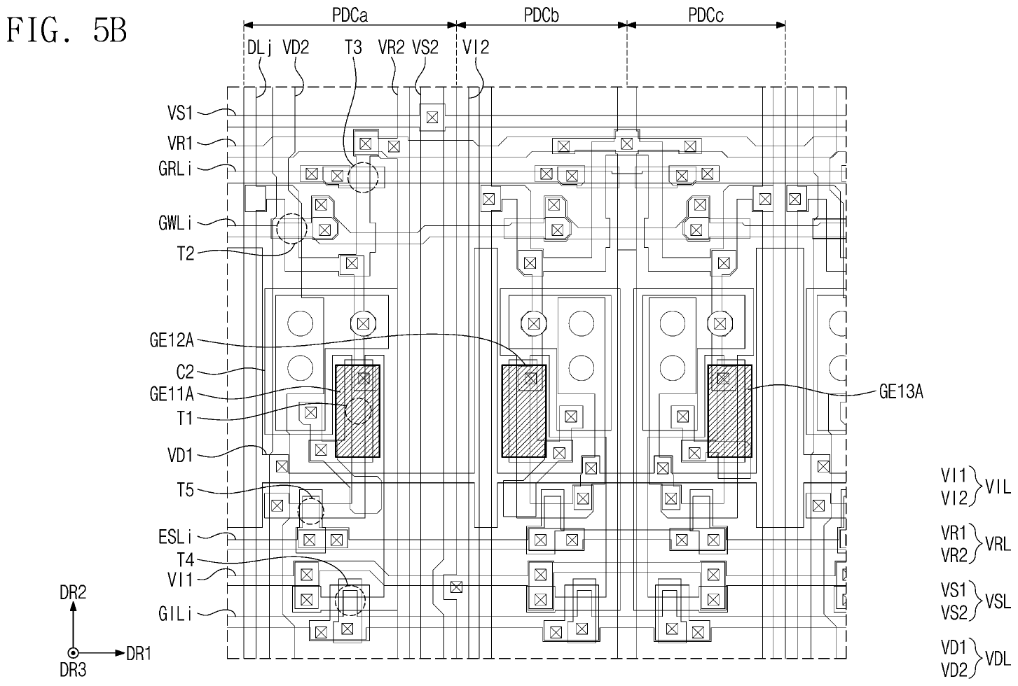

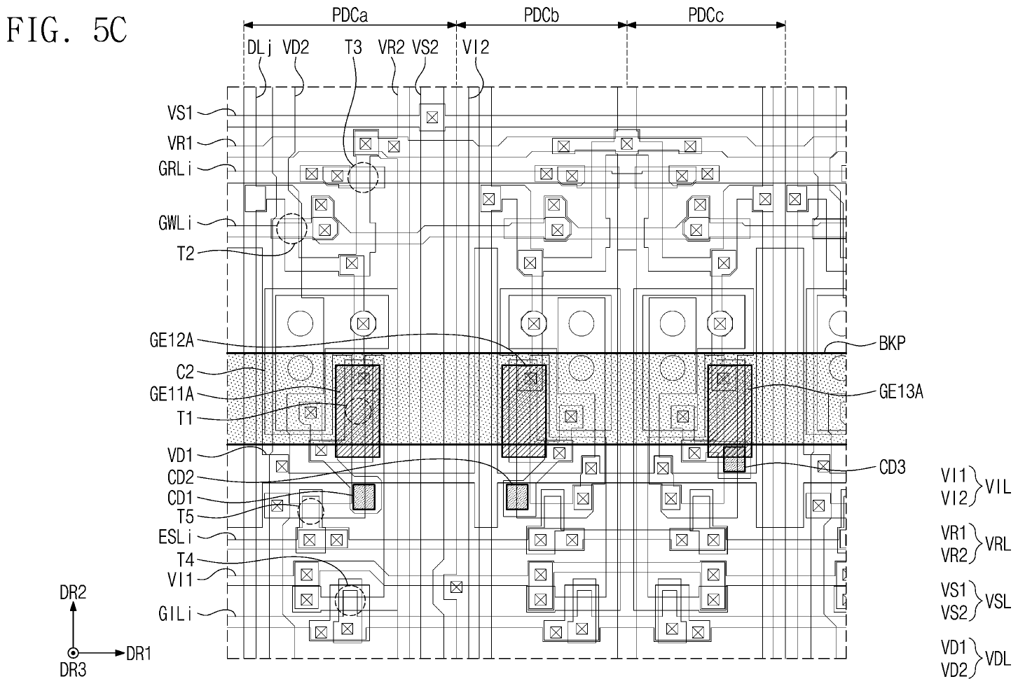

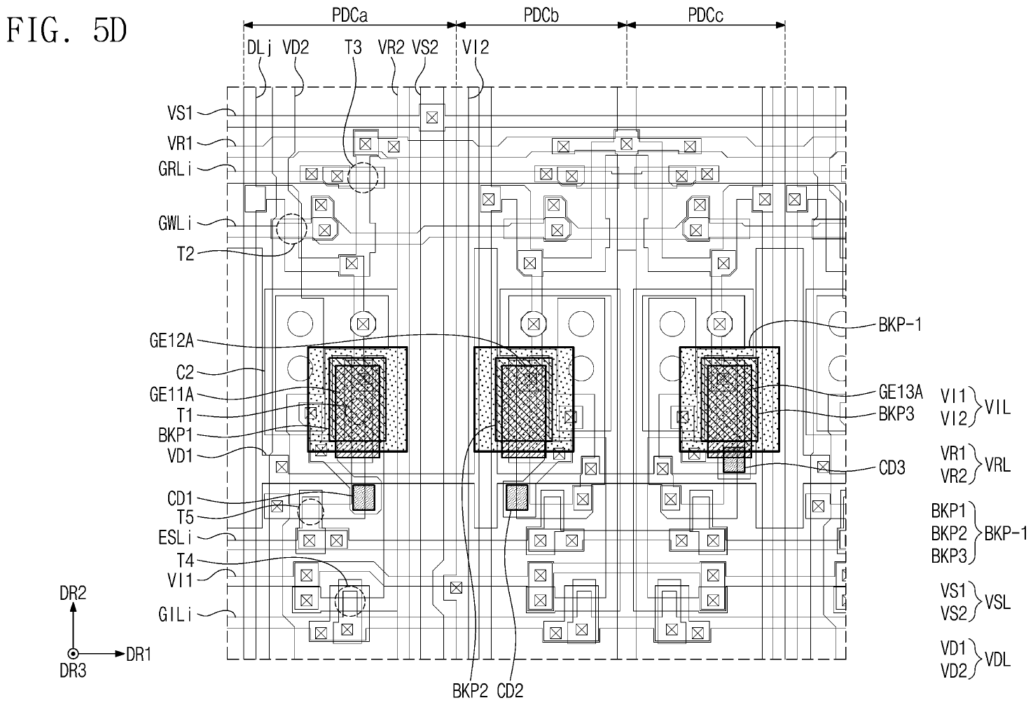

FIG. 5A to FIG. 5D are schematic plan views illustrating a portion of a display panel according to an embodiment of the disclosure. FIG. 5A to FIG. 5D may be drawings corresponding to the pixels PXij-3 illustrated in FIG. 2D. Hereinafter, redundant descriptions will be omitted.

FIG. 5A and FIG. 5B illustrate a driving element layer DDL, and FIG. 5C and FIG. 5D illustrate the driving element layer DDL and blocking patterns BKP and BKP-1. Multiple pixel drivers PDC-3 may be provided, and FIG. 5A to FIG. 5D illustrate a region in which three pixel drivers PDCa, PDCb, and PDCc arranged along the first direction DR1 are disposed. The driving element layer DDL may include the pixel driver PDC-3 illustrated in FIG. 2D. Therefore, each of the pixel drivers PDCa, PDCb, and PDCc is illustrated as including five transistors T1 to T5 and two capacitors C1 and C2.

Referring to FIG. 5A, a horizontal voltage line VD1 (hereinafter, a first horizontal power line VD1) constituting a first power line VDL, a horizontal voltage line VS1 constituting a second power line VSL, a horizontal voltage line VR1 constituting a reference voltage line VRL, a reset scan line GRLi, a write scan line GWLi, an emission line ESLi, a horizontal voltage line VI1 (hereinafter, a fourth horizontal power line) constituting an initialization voltage line VIL, and a first initialization scan line GILi are each extended along the first direction DR1 and arranged along the second direction DR2. A data line DLj, a vertical voltage line VD2 constituting the first power line VDL, a vertical voltage line VS2 (hereinafter, a second vertical power line VS2) constituting the second power line VSL, a vertical voltage line VR2 constituting the reference voltage line VRL, and a vertical voltage line VI2 constituting the initialization voltage line VIL are each extended along the second direction DR2 and arranged along the first direction DR1.

In the region illustrated in FIG. 5A, referring to the pixel driver PDCa disposed on the leftmost side, the third transistor T3 may be disposed overlapping the reset scan line GRLi, and the second transistor T2 may be disposed overlapping the write scan line GWLi. The fifth transistor T5 including a gate connected to the emission line ESLi may be disposed on an upper side of the emission line ESLi, and the fourth transistor T4 including a gate connected to the first initialization scan line GILi may be disposed between the fourth horizontal power line VI1 and the first initialization scan line GILi.

The first transistor T1 may be disposed between the write scan line GWLi and the first horizontal power line VD1. The first capacitor C1 may be formed overlapping the first transistor T1, and the second capacitor C2 may be formed at a position adjacent to the first transistor T1.

For case of description, FIG. 5B highlights and illustrates gates GE11A, GE12A, and GE13A of the first transistor T1 among components illustrated in FIG. 5A. Referring to FIG. 5B, the gates GE11A, GE12A, and GE13A of the first transistor T1 respectively constituting the pixel drivers PDCa, PDCb, and PDCc are disposed spaced apart in the first direction DR1. In an embodiment, the gates GE11A, GE12A, and GE13A of the first transistor T1 may be aligned in the first direction DR1. In a plan view, each of the gates GE11A, GE12A, and GE13A of the first transistor T1 may overlap or be spaced apart from a corresponding driver connection part CD1, CD2 or CD3.

Referring to FIG. 5C, the blocking pattern BKP may be disposed on the driving element layer DDL. Specifically, the blocking pattern BKP may be disposed on the gates GE11A, GE12A, and GE13A of the first transistor T1. The blocking pattern BKP may overlap, in a plan view, the gates GE11A, GE12A, and GE13A of the first transistor T1.

As described above, the blocking pattern BKP may block between the gates GE11A, GE12A, and GE13A of the first transistor T1 and an anode. Therefore, the blocking pattern BKP may overlap, in a plan view, at least a portion overlapping the anode among the gates GE11A, GE12A, and GE13A of the first transistor T1. Accordingly, the above-described first node N1 (see FIG. 2D) may be electrically blocked. The first node N1 may additionally form a capacitance in relation to the anode in addition to the first capacitor C1 (see FIG. 2D). The capacitance formed with the anode may be different for each light emitting portion, and accordingly, luminance non-uniformity may occur in a display region DA. According to the disclosure, by further including the blocking pattern BKP between the first node N1 and the anode, it may be possible to prevent coupling between a light emitting portion and the first node N1. Accordingly, according to the disclosure, the occurrence of a moire phenomenon, stains, or the like may be prevented, and an image having uniform luminance without a difference between light emitting portions may be displayed.

In an embodiment, the blocking pattern BKP may have a bar shape extended along the first direction DR1. Accordingly, one blocking pattern BKP may simultaneously block the gates GE11A, GE12A, and GE13A of first transistors T1 of one row arranged along the first direction DR1.

Although not illustrated, the blocking pattern BKP may be connected to any one overlapping first power line VDL. In other embodiments, the blocking pattern BKP may be connected to a separately provided power line to be provided with a unique power voltage. The power line may be provided in the display region DA or may be provided in a non-display region NDA (e.g. refer to FIG. 3A). In other embodiments, the blocking pattern BKP may be connected to another power line to receive a transmitted power voltage. As long as the blocking pattern BKP may receive a constant voltage, connection between the blocking pattern BKP and a power line may be provided at various positions, and is not limited to any one embodiment.

In other embodiments, referring to FIG. 5D, multiple blocking patterns BKP-1 (i.e. multiple blocking patterns BKP1, BKP2 and BKP3) may be provided. The blocking patterns BKP-1 may be spaced apart from each other along the first direction DR1 and may overlap the gates GE11A, GE12A, and GE13A of the first transistor T1. The gates GE11A, GE12A, and GE13A of the first transistor T1 may be electrically blocked by the blocking patterns BKP-1, respectively. The blocking patterns BKP-1 may be connected to a power line by passing through at least one insulation layer (e.g., a sixth insulation layer) disposed in a lower portion thereof to receive a power voltage.

The blocking patterns BKP and BKP-1 according to the disclosure may be provided in various shapes as long as they may electrically block the gates GE11A, GE12A, and GE13A of the first transistor T1 by overlapping, in a plan view, the gates GE11A, GE12A, and GE13A of the first transistor T1, and are not limited to any one embodiment.

According to the disclosure, the display panel may prevent coupling between the first transistor T1 and a light emitting element by further including the blocking patterns BKP and BKP-1 disposed on the first transistor T1. Accordingly, a problem in which the potential of a gate node of the first transistor T1 is different for each pixel is prevented, so that a defect of the occurrence of a luminance difference for each region in the display region DA may be prevented.

FIG. 6 is a schematic cross-sectional view of a portion of a display panel according to an embodiment of the disclosure. FIG. 6 illustrates a portion of the pixel PXij-3 illustrated in FIG. 2D. Referring to FIG. 6, a display panel DP may include a base layer BS, a driving element layer DDL, a light emitting element layer LDL, an encapsulation layer ECL, and a sensing layer ISL. Illustratively, FIG. 6 illustrates a cross-section of one region among regions in which one light emitting portion is disposed.

The base layer BS may be a member which provides a base surface on which a pixel driver PDC-3 may be disposed. The base layer BS may be a rigid substrate, or a flexible substrate capable of bending, folding, rolling, and the like. The base layer BS may be a glass substrate, a metal substrate, a polymer substrate, and/or the like. However, embodiments of the disclosure are not limited thereto, and the base layer BS may be an inorganic layer, an organic layer, and/or a composite material layer.

The base layer BS may have a multi-layered structure. The base layer BS may include a first polymer resin layer, a silicon oxide (SiOₓ) layer disposed on the first polymer resin layer, an amorphous silicon (a-Si) layer disposed on the silicon oxide layer, and a second polymer resin layer disposed on the amorphous silicon layer. The silicon oxide layer and the amorphous silicon layer may be referred to as a base barrier layer.

The polymer resin layer may include a polyimide-based resin. The polymer resin layer may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, and a perylene-based resin. In the disclosure, “˜˜-based” resin means that a functional group of “˜˜” is included.

Each of insulation layers, conductive layers, and semiconductor layers disposed on the base layer BS may be formed by coating, deposition, and/or the like. Thereafter, an insulation layer, a semiconductor layer, and a conductive layer may be selectively patterned through performing a photolithography process multiple times to form a hole in the insulation layer, or to form a semiconductor pattern, a conductive pattern, a signal line, and the like.

The driving element layer DDL may include first to fifth insulation layers 10, 20, 30, 40, and 50 and the pixel driver PDC-3 stacked on each other on the base layer BS. FIG. 6 illustrates two transistors TR and T1 and two capacitors C1 and C2 of the pixel driver PDC-3. The transistors TR and T1 may include a connection transistor TR and a first transistor T1.

The connection transistor TR may be a transistor except for the first transistor T1 among transistors connected to a light emitting element LD-1 through a connection wire CN (e.g. refer to FIG. 4B). In an embodiment, the pixel driver PDC-3 in FIG. 6 may include the pixel driver PDC-3 illustrated in FIG. 2D, so that the connection transistor TR may correspond to the fourth transistor T4.

On the base layer BS, the first insulation layer 10 may be disposed. The first insulation layer 10 may be an inorganic layer and/or an organic layer, and may have a single-layered or multi-layered structure. The first insulation layer 10 may include at least one of an aluminum oxide, a titanium oxide, a silicon oxide, a silicon nitride, a silicon oxynitride, a zirconium oxide, and a hafnium oxide. In an embodiment, the first insulation layer 10 is illustrated as a single-layered silicon oxide layer. Insulation layers to be described later may be inorganic layers and/or organic layers, and may have a single-layered structure or multi-layered structure. The inorganic layer may include at least one of the above-described materials, but is not limited thereto.

The first insulation layer 10 may cover a lower conductive layer BCL. For example, the display panel DP may further include the lower conductive layer BCL disposed overlapping the connection transistor TR. The lower conductive layer BCL may block an electric potential due to polarization of the base layer BS from affecting the connection transistor TR. The lower conductive layer BCL may block light incident to the connection transistor TR from a lower portion. Between the lower conductive layer BCL and the base layer BS, at least one of an inorganic barrier layer and a buffer layer may be further disposed.

The lower conductive layer BCL may include a reflective metal. For example, the lower conductive layer BCL may include titanium (Ti), molybdenum (Mo), an alloy containing molybdenum, aluminum (Al), an alloy containing aluminum, an aluminum nitride (AlN), tungsten (W), a tungsten nitride (WN), copper (Cu), and/or the like.

In an embodiment, the lower conductive layer BCL may be connected to a source region SR of the connection transistor T1 through a source electrode pattern W1. The lower conductive layer BCL may be synchronized with the source region SR of the connection transistor TR. However, this is only an example, and the lower conductive layer BCL may be connected to a gate electrode GE of the connection transistor TR and synchronized with the gate electrode GE. In other embodiments, the lower conductive layer BCL may be connected to another electrode and independently applied with a constant voltage or a pulse signal. In other embodiments, the lower conductive layer BCL may be provided in an isolated form from another conductive pattern. The lower conductive layer BCL according to an embodiment of the disclosure may be provided in various forms, and is not limited to any one embodiment.

On the first insulation layer 10, the connection transistor TR may be disposed. The connection transistor TR may include a semiconductor pattern SP and a gate electrode GE. The semiconductor pattern SP may be disposed on the first insulation layer 10. The semiconductor pattern SP may include an oxide semiconductor. For example, the oxide semiconductor may include a transparent conductive oxide (TCO) such as an indium tin oxide (ITO), an indium zinc oxide (IZO), an indium gallium zinc oxide (IGZO), a zinc oxide (ZnO), an indium oxide (In₂O₃), and/or the like. However, embodiments of the disclosure are not limited thereto, and the semiconductor pattern SP may include amorphous silicon, low-temperature polycrystalline silicon, and/or polycrystalline silicon.

On the second insulation layer 20, the connection transistor TR may be disposed. Among transistors constituting the pixel driver PDC-3, the connection transistor TR may be a transistor most adjacent to and connected to the light emitting element LD-1 without another transistor or capacitor interposed therebetween. In case that the pixel driver is the pixel driver PDC-2 illustrated in FIG. 2C, the connection transistor TR may be the first transistor T1.

The connection transistor TR may include a semiconductor pattern SP and a gate electrode GE. The semiconductor pattern SP may be disposed on the second insulation layer 20.

The semiconductor pattern SP may include an oxide semiconductor. For example, the oxide semiconductor may include a transparent conductive oxide (TCO) such as an indium tin oxide (ITO), an indium zinc oxide (IZO), an indium gallium zinc oxide (IGZO), a zinc oxide (ZnO), an indium oxide (In₂O₃), and/or the like. However, embodiments of the disclosure are not limited thereto, and the semiconductor pattern SP may include amorphous silicon, low-temperature polycrystalline silicon, and/or polycrystalline silicon.

The semiconductor pattern SP may include a source region SR, a drain region DR, and a channel region CR, which are divided according to the degree of conductivity. The channel region CR may be a portion of the semiconductor pattern SP overlapping the gate electrode GE in a plan view. The source region SR and the drain region DR may be portions of the semiconductor pattern SP spaced apart from each other with the channel region CR interposed therebetween.

The source region SR and the drain region DR may have relatively high conductivity compared to the channel region CR. The source region SR may correspond to a source electrode of the connection transistor TR, and the drain region DR may correspond to a drain electrode of the connection transistor TR.

On the semiconductor pattern SP, the third insulation layer 30 may be disposed. The third insulation layer 30 may be disposed on the second insulation layer 20 so as to cover the semiconductor pattern SP. In FIG. 6, on the semiconductor pattern SP, the second insulation layer 20 may be disposed. The second insulation layer 20 may be disposed on the first insulation layer 10 so as to cover the semiconductor pattern SP.

On the third insulation layer 30 (or the second insulation layer 20), the gate electrode GE of the connection transistor TR may be disposed. The gate electrode GE may be disposed on the semiconductor pattern SP and overlap the channel region CR. The gate electrode GE of the connection transistor TR may function as a gate of the connection transistor TR.

On the gate electrode GE, the fourth insulation layer 40 may be disposed. The fourth insulation layer 40 may be disposed on the third insulation layer 30 so as to cover the gate electrode GE. On the fourth insulation layer 40, the fifth insulation layer 50 may be disposed, and on the fifth insulation layer 50, the source electrode pattern W1 and a drain electrode pattern W2 may be disposed. In FIG. 6, on the gate electrode GE, the third insulation layer 30 may be disposed. The third insulation layer 30 may be disposed on the second insulation layer 20 so as to cover the gate electrode GE. On the third insulation layer 30, the fourth insulation layer 40 may be disposed, and on the fourth insulation layer 40, the source electrode pattern W1 and a drain electrode pattern W2 may be disposed. The first to fifth insulation layers 10 to 50 may be inorganic layers or organic layers.

The source electrode pattern W1 may be connected to a source region SR of the connection transistor TR through a first contact-hole CNT1 defined in the third, fourth, and fifth insulation layers 30, 40, and 50 (or the second, third, and fourth insulation layers 20, 30, and 40). The source electrode pattern W1 and the source region SR of the semiconductor pattern SP may function as a source of the connection transistor TR.

The drain electrode pattern W2 may be connected to a drain region DR the connection transistor TR through a second contact-hole CNT2 defined in the second to fourth insulation layers 20, 30, and 40. The drain electrode pattern W2 and the drain region DR of the semiconductor pattern SP may function as a drain of the connection transistor TR. On the source electrode pattern W1 and the drain electrode pattern W2, the fifth insulation layer 50 may be disposed.

A first capacitor electrode CPE1 and a second capacitor electrode CPE2 constitute the first capacitor C1. The first capacitor electrode CPE1 and the second capacitor electrode CPE2 may be spaced apart from each other with the first insulation layer 10 and the second insulation layer 20 interposed therebetween. The first capacitor electrode CPE1 may be connected to the above-described first node N1, and the second capacitor electrode CPE2 may be connected to the above-described third node N3. The second capacitor electrode CPE2 and a third capacitor electrode CPE3 may constitute the second capacitor C2.

In an embodiment of the disclosure, the first capacitor electrode CPE1 and the lower conductive layer BCL may have a shape of a single body. The second capacitor electrode CPE2 and the gate electrode GE may have a shape of a single body.

The first transistor T1 is illustrated as having a structure corresponding to that of the connection transistor TR. Specifically, the first transistor T1 may include a gate electrode GE1 disposed between the second insulation layer 20 and the third insulation layer 30, and a semiconductor pattern SP1 (hereinafter, a first semiconductor pattern SP1) disposed between the first insulation layer 10 and the second insulation layer 20. The first semiconductor pattern SP1 may include a channel region CR1, a source region SR1, and a drain region DR1.

A lower conductive layer BCL1 (hereinafter, a first lower conductive layer BCL1) overlapping the first transistor T1 may be disposed between the base layer BS and the first insulation layer 10. Referring to FIG. 2D, the first lower conductive layer BCL1 may be connected to the second capacitor electrode CPE2 and function as a lower gate electrode of the first transistor T1.

A source electrode pattern W11 connected to the source region SR1 and a drain electrode pattern W21 connected to the drain region DR1 may be disposed between the fourth insulation layer 40 and the fifth insulation layer 50. The source electrode pattern W11 and the drain electrode pattern W21 are connected to the source region SR1 and the drain region DR1 through through-holes CNT11 and CNT21, respectively.

This is only an example, and the first transistor T1 may have a structure different than the connection transistor TR, and is not limited to any one embodiment.

A sixth insulation layer 60 may be disposed on the fifth insulation layer 50. The sixth insulation layer 60 may include an organic material and may provide a flat surface in an upper portion, but is not limited thereto.

The light emitting element LD-1 may be disposed on the sixth insulation layer 60. The light emitting element LD-1 may be connected to the connection transistor TR through a contact-hole CNT3 defined passing through the fifth insulation layer 50 and the sixth insulation layer 60.

A pixel definition film PDL may be disposed on the sixth insulation layer 60. The pixel definition film PDL may be an organic layer. In an embodiment, the pixel definition film PDL may have properties of absorbing light, and for example, may have a black color. The pixel definition film PDL may be a light blocking pattern having light blocking properties.

The light emitting element LD-1 may include a first electrode EL1, a middle layer IML, and a second electrode EL2. The first electrode EL1 may be disposed on the sixth insulation layer 60. The first electrode EL1 may overlap the first transistor T1 in a plan view. In the pixel definition film PDL, an opening OP-PDL (hereinafter, a light emitting opening OP-PDL) which exposes a portion of the first electrode EL1 may be defined. The light emitting opening OP-PDL may have the components of the light emitting element LD-1 overlapped and disposed therein, and may be substantially a region in which light emitted by the light emitting element LD-1 is displayed. The shape of the above-described light emitting portions EP_R, EP_G, and EP_B, (see FIG. 4B) may substantially correspond to the shape of the light emitting opening OP-PDL in a plan view.

The middle layer IML may be disposed on the pixel definition film PDL. The middle layer IML may be disposed between the first electrode EL1 and the second electrode EL2. The middle layer IML may include a light emitting layer EML and a functional layer FNL. The light emitting element LD-1 may include the middle layer IML of various structures, and is not limited to any one embodiment. For example, the functional layer FNL may be provided as multiple layers, and may be provided as two or more layers spaced apart from each other with the light emitting layer EML interposed therebetween.

The light emitting layer EML may include an organic light emitting material. The light emitting layer EML may include an inorganic light emitting material, or may include a mixed layer of an organic light emitting material and an inorganic light emitting material. The light emitting layer EML may generate light of any one of blue, red, and green colors.

The functional layer FNL may be disposed between the first electrode EL1 and the second electrode EL2. The functional layer FNL may be disposed between the first electrode EL1 and the light emitting layer EML and between the second electrode EL2 and the light emitting layer EML. The light emitting layer EML may also be disposed in the light emitting opening OP-PDL and on a portion adjacent to the light emitting opening OP-PDL.

The functional layer FNL may control the movement of charges between the first electrode EL1 and the second electrode EL2. The functional layer FNL may include a hole injection/transport material and/or an electron injection/transport material. The functional layer FNL may include at least one of an electron blocking layer, a hole transport layer, a hole injection layer, a hole blocking layer, an electron transport layer, an electron injection layer, and a charge generation layer.

The second electrode EL2 may be disposed on the middle layer IML. In an embodiment, the second electrode EL2 may be entirely formed on the base layer BS. For example, light emitting elements LD-1 adjacent to each other may include a common second electrode EL2. However, this is only an example, and the second electrode EL2 may be independently provided to each light emitting element LD-1, and is not limited to any one embodiment.

On the light emitting element layer LDL, the encapsulation layer ECL may be disposed. The encapsulation layer ECL may cover the light emitting element LD-1. The encapsulation layer ECL may include a first inorganic layer IL1, an organic layer OL, and a second inorganic layer IL2, which may be stacked on each other.

The first and second inorganic layers IL1 and IL2 may protect the light emitting element LD-1 from moisture and oxygen outside the display panel DP. The organic layer OL may protect the light emitting element LD-1 from foreign materials such as particles remaining in the process of forming the first inorganic layer IL1.

The sensing layer ISL may sense an external input. In an embodiment, the sensing layer ISL may be formed on the encapsulation layer ECL through a continuous process. The sensing layer ISL may include multiple conductive layers and multiple insulation layers. The conductive layers may include a first sensing conductive layer MTL1 and a second sensing conductive layer MTL2, and the insulation layers may include first to third sensing insulation layers 71, 72, and 73.

The first sensing conductive layer MTL1 may be disposed between the first sensing insulation layer 71 and the second sensing insulation layer 72, and the second sensing conductive layer MTL2 may be disposed between the second sensing insulation layer 72 and the third sensing insulation layer 73. A portion of the second sensing conductive layer MTL2 may be connected to the first sensing conductive layer MTL1 through a contact-hole CNT formed in the second sensing insulation layer 72.

The first sensing conductive layer MTL1 and the second sensing conductive layer MTL2 may constitute a sensor configured to sense an external input. The sensor may be driven in a capacitive manner, and may be driven in any of an mEPUual-cap capacitive manner or a self-cap capacitive manner.

Each of the first sensing conductive layer MTL1 and the second sensing conductive layer MTL2 may include a transparent conductive oxide, or may have a metal mesh shape formed of an opaque conductive material. The first sensing conductive layer MTL1 and the second sensing conductive layer MTL2 may have various materials and various shapes as long as the visibility of an image displayed by the display panel DP is not degraded, and are not limited to any one embodiment.

The blocking pattern BKP may be disposed between the fifth insulation layer 50 and the sixth insulation layer 60. The blocking pattern BKP may be positioned between the first transistor T1 and the light emitting element LD-1. The blocking pattern BKP may electrically shield between the gate electrode GE1 of the first transistor T1 and the light emitting element LD-1, particularly the first electrode EL1.

The blocking pattern BKP may overlap the first transistor T1. Specifically, the blocking pattern BKP may overlap the gate electrode GE1 of the first transistor T1. In an embodiment, the blocking pattern BKP is illustrated as having a bar shape extended along the first direction DR1 (e.g. refer to FIG. 4A) and overlapping multiple gates of the first transistors T1. The blocking pattern BKP may be extended along a direction intersecting the direction in which each of gates GE11A, GE12A, and GE13A (e.g. refer to FIG. 5B) of the first transistor T1 are extended. The blocking pattern BKP may overlap, in a plan view, the gates GE11A, GE12A, and GE13A of the first transistor T1.

The blocking pattern BKP may be connected to a connection wire CNW. In an embodiment, it is illustrated that the connection wire CNW and electrode patterns W1, W2, W11, and W21 are disposed on (or in) the same layer, but this is only an example, and the connection wire CNW and the electrode patterns W1, W2, W11, and W21 may be disposed on (or in) different layers, or the connection wire CNW and the blocking pattern BKP may be disposed on (or in) the same layer, but embodiments of the disclosure are not limited thereto.

The connection wire CNW may transmit a constant voltage, and may transmit, for example, a power voltage. For example, the connection wire CNW may be the second vertical power line VS2 illustrated in FIG. 5A, but is not limited thereto. In an embodiment, it is illustrated that the connection wire CNW passes through a light emitting region and connection between the blocking pattern BKP and the connection wire CNW is achieved in the corresponding light emitting region, but embodiments of the disclosure are not limited thereto, and the connection wire CNW may be disposed in a peripheral region, and the blocking pattern BKP may be extended to the peripheral region, thereby achieving the connection in the peripheral region.

The blocking pattern BKP may receive a predetermined or selected voltage. The blocking pattern BKP receives a power voltage. Accordingly, the gates GE11A, GE12A, and GE13A (e.g. refer to FIG. 5B) of the first transistor T1 may be electrically shielded. The blocking pattern BKP overlaps the gate of the first transistor T1 in a plan view to electrically shield between the gate of the first transistor T1 and the light emitting element LD (see FIG. 2A to FIG. 2D). Accordingly, the potential of the above-described first node N1 (see FIG. 2A to FIG. 2D) may be stabilized without being changed for each pixel.

The blocking pattern BKP may be connected to any one of voltage wires. In an embodiment, it is illustrated that the blocking pattern BKP may be connected to a second vertical power line VS2 (e.g. refer to FIG. 5A) constituting a second power line VSL (e.g. refer to FIG. 5A) to receive a second power voltage VSS (e.g. refer to FIG. 2A), but embodiments of the disclosure are not limited thereto, and the blocking pattern BKP may be connected to a horizontal voltage line VS1 (e.g. refer to FIG. 5A) constituting the second power line VSL. In other embodiments, the blocking pattern BKP may be connected to a separate power line (not shown) to receive a second power voltage.

In other embodiments, the blocking pattern BKP may receive a first power voltage. The blocking pattern BKP may be connected to a first power line VDL (e.g. refer to FIG. 5A), or connected to a separate power line to receive the first power voltage. In other embodiments, the blocking pattern BKP may be connected to a line which transmits a power voltage, such as an initialization voltage line, a compensation voltage line, or a reset voltage line, or may be connected to a separately provided voltage line to receive a power voltage. The disclosure is not is not limited to any one embodiment.

The blocking pattern BKP may be disposed on the driving element layer DDL. In an embodiment, the blocking pattern BKP may be disposed between the fifth insulation layer 50 and the sixth insulation layer 60. Accordingly, the blocking pattern BKP may be designed in various shapes independent of components of the pixel driver PDC-3. However, this is only an example, and the blocking pattern BKP may be formed in the driving element layer DDL as long as it may be disposed between the gate electrode GE1 of the first transistor T1 and the light emitting element LD-1 and overlaps the gate electrode GE1 of the first transistor T1 in a plan view, and is not limited to any one embodiment.

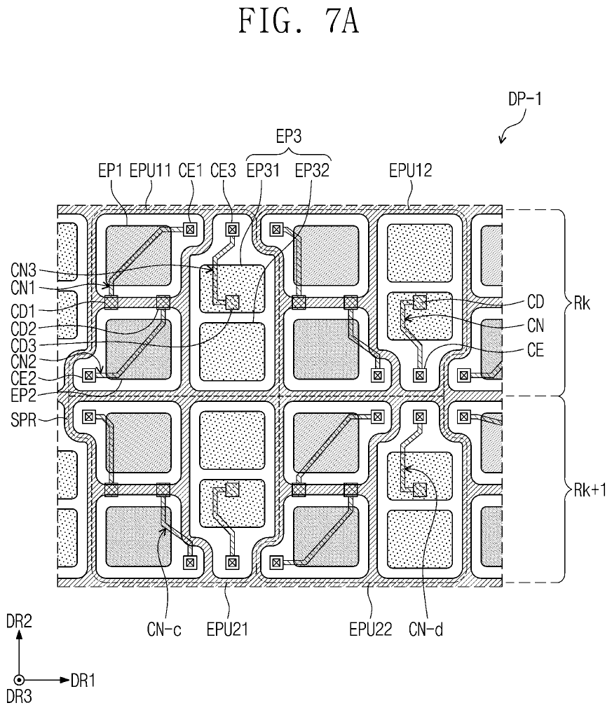

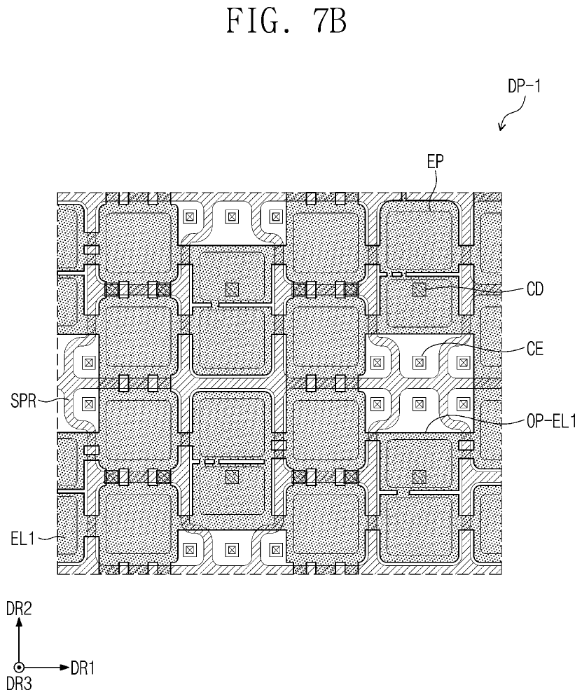

FIG. 7A and FIG. 7B are schematic plan views of a display panel according to an embodiment of the disclosure. FIG. 8A to FIG. 8C are schematic cross-sectional views of a display panel according to an embodiment of the disclosure. FIG. 8B is an enlarged view of a first region AA illustrated in FIG. 8A. FIG. 8C is an enlarged view of a second region BB illustrated in FIG. 8A. FIG. 8A illustrates a portion of the pixel PXij illustrated in FIG. 2A, and illustrates a region corresponding to FIG. 6. Hereinafter, redundant descriptions will be omitted.

Referring to FIG. 7A, a display panel DP-1 may include light emitting units EPU11 and EPU12 arranged in a row Rk and light emitting units EPU21 and EPU22 arranged in a row Rk+1. Each of the light emitting units EPU11 and EPU12 and the light emitting units EPU21 and EPU22 may include light emitting portions EP1, EP2, and EP3, and the light emitting portion EP3 may include a first portion EP31 and a second portion EP32. As illustrated in FIG. 7A, in the display panel DP-1, a connection between a light emitting element LD (see FIG. 8A) and a pixel driver PDC (see FIG. 8A) may be achieved through a connection wire CN and a second electrode EL2 (see FIG. 8A) of the light emitting element LD. For example, the display panel DP-1 may further include a connection wire CN (e.g. connection wires CN1, CN2, CN3, CN-c, and CN-d) and a separator SPR. The second electrode EL2 may be separated for each light emitting portion EP (e.g. refer to FIG. 7B) by the separator SPR. The separated second electrodes EL2 and a corresponding pixel driver PDC may be connected to each other through the connection wire CN. Accordingly, the emission connection part CE and the driver connection part CD which are illustrated in FIG. 4B may be respectively defined on a side and another side of the connection wire CN.

The side of the connection wire CN which may be connected to a connection transistor TR may be defined as the driver connection part CD (e.g. a driver connection part CD1, CD2, or CD3), and the another side of the connection wire CN which may be connected to the light emitting element LD may be defined as the emission connection part CE (e.g. an emission connection part CE1, CE2, or CE3). Since the display panel DP-1 may further include the connection wire CN, even if connection portions of the connection transistor TR and the light emitting element LD are designed at positions spaced apart in a plan view, electrical connection between the pixel driver PDC and the light emitting element LD may be readily achieved.

The driver connection part CD may be connected to the drain electrode pattern W2 through a third contact-hole CNT3 defined in a fifth insulation layer 50. Accordingly, the connection wire CN may be electrically connected to the connection transistor TR through the driver connection part CD.

The emission connection part CE may be electrically connected to the second electrode EL2 of the light emitting element LD through an opening passing through the sixth insulation layer 60 and a pixel definition film PDL. The opening may include a first opening OP1 defined in the sixth insulation layer 60 and a second opening OP2 defined in the pixel definition film PDL. The planar area of the second opening OP2 may be greater than that of the first opening OP1. The first opening OP1 and the second opening OP2 may be formed through a separate process. However, this is only an example, and the first opening OP1 and the second opening OP2 may be formed through the same process at a time, and are not limited to any one embodiment.

The first opening OP1 exposes at least a portion of the connection wire CN, and the second opening OP2 is formed at a position overlapping the first opening OP1. The portion of the connection wire CN exposed from the sixth insulation layer 60 may be defined as the emission connection part CE.

Referring to FIG. 8A and FIG. 8B, the connection wire CN may be disposed between a fifth insulation layer 50 and the sixth insulation layer 60. The connection wire CN may electrically connect the connection transistor TR and the light emitting element LD. The emission connection part CE may be the portion of the connection wire CN exposed from the sixth insulation layer 60, and may be a portion of the connection wire CN to which the light emitting element LD may be connected. In an embodiment, the connection wire CN may be connected to the second electrode EL2 of the light emitting element LD, and may be spaced apart from a first electrode EL1 in a plan view.

Referring to FIG. 7B and FIG. 8A, the first electrode EL1 may be connected to the first power line VDL (see FIG. 2A) to receive the first power voltage VDD (see FIG. 2A). The first electrode EL1 may have a shape of a single body. The emission connection part CE connected to the second electrode EL2 may be provided at a position overlapping an opening OP-EL1 defined in the first electrode EL1.

Referring back to FIG. 8A and FIG. 8B, a tip portion TP may be defined in the emission connection part CE. The sixth insulation layer 60 and the pixel definition film PDL may expose at least a portion of the tip portion TP and at least a portion of a second side surface L2_W.

The connection wire CN may have a three-layered structure. The connection wire CN may include a first layer L1, a second layer L2, and a third layer L3, which may be stacked on each other. The second layer L2 may include a material different than the first layer L1 and the third layer L3. The second layer L2 may be relatively thicker than the first layer L1 and the third layer L3. The second layer L2 may include a highly conductive material. In an embodiment, the second layer L2 may include aluminum (Al).

The first layer L1 may include a material having a lower etch rate than that of the second layer L2. In an embodiment, the first layer L1 may include titanium (Ti), and the second layer L2 may include aluminum (Al). A side surface L1_W of the first layer L1 may be defined further outside than the side surface L2_W of the second layer L2.

The third layer L3 may include a material having a lower etch rate than that of the second layer L2. In an embodiment, the third layer L3 may include titanium (Ti). A side surface L3_W of the third layer L3 may be defined further outside than the side surface L2_W of the second layer L2.

The side surface L1_W the first layer L1 and the side surface L3_W of the third layer L3 may protrude further outward than the side surface L2_W of the second layer L2. The side surface L2_W the second layer L2 may be recessed further inward than the side surface L1_W of the first layer L1 and the side surface L3_W of the third layer L3. Due to the above configuration, the emission connection part CE of the connection wire CN may have an undercut shape or an overhang structure. The tip portion TP of the emission connection part CE may be defined by a portion of the third layer L3 further protruded than the second layer L2.

The second electrode EL2 may be connected to the connection wire CN and be electrically connected to the pixel driver PDC. For example, the second electrode EL2 may be electrically connected to the connection transistor TR through the connection wire CN.

A middle layer IML may also be disposed on a portion of the sixth insulation layer 60 exposed by a second opening OP2 of a pixel definition film PDL. The middle layer IML may also be disposed on a portion of the connection wire CN exposed by the first opening OP1 of the sixth insulation layer 60. The middle layer IML disposed on the portion of the sixth insulation layer 60 and the portion of the connection wire CN may be a functional layer FNL.

As illustrated in FIG. 8B, the middle layer IML may include one end IN1 disposed along an upper surface of the sixth insulation layer 60 and the other end IN2 disposed along an upper surface of the tip portion TP. When viewed on a cross-section, the middle layer IML may have a shape of being partially disconnected with respect to the tip portion TP in a region in which the emission connection part CE is defined. However, when viewed in a plan view, the middle layer IML may have a shape of a single body entirely connected within a region defined by the separator SPR.

The second electrode EL2 disposed on the middle layer IML may also be disposed on the portion of the sixth insulation layer 60 exposed by the second opening OP2 of the pixel definition film PDL. The second electrode EL2 may also be disposed on the portion of the connection wire CN exposed by the first opening OP1 of the sixth insulation layer 60.

As illustrated in FIG. 8B, the second electrode EL2 may include one end EN1 disposed along the upper surface of the fifth insulation layer 60 and the other end EN2 disposed along of the upper surface of the tip portion TP. When viewed on a cross-section, the second electrode EL2 may have a shape of being partially disconnected with respect to the tip portion TP in the region in which the emission connection part CE is defined. However, when viewed in a plan view, the second electrode EL2 may have a shape of a single body entirely connected within the region defined by the separator SPR.

The one end EN1 of the second electrode EL2 may be disposed along a side surface L2_W of the second layer L2 and be in contact with the side surface L2_W of the second layer L2. Therefore, the second electrode EL2 may be connected to the second layer L2. Accordingly, the light emitting element LD may be electrically connected to the pixel driver PDC through the connection wire CN.

The other end IN2 of the middle layer IML and the other end EN2 of the second electrode EL2 may cover the side surface L3_W of the third layer L3. However, embodiments of the disclosure are not limited thereto, and at least a portion of the side surface L3_W of the third layer L3 may be exposed from the other end IN2 of the middle layer IML and/or the other end EN2 of the second electrode EL2.

In an embodiment, the second electrode EL2 and the middle layer IML may be formed by being commonly deposited in multiple pixels through an open mask. At this time, the second electrode EL2 and the middle layer IML may be separated by the separator SPR. Therefore, the second electrode EL2 and the middle layer IML may be electrically independent of each adjacent pixel.

Referring to FIG. 8A and FIG. 8C, a light emitting element layer LDL-1 may further include a separator SPR. The separator SPR may be disposed on the pixel definition film PDL, and may be covered by an encapsulation layer ECL. The separator SPR may have a shape of a single body surrounding each of light emitting portions EP1, EP2, and EP3. For example, the separator SPR may have a mesh shape in which openings respectively corresponding to the light emitting portions EP1, EP2, and EP3 are defined. The separator SPR may disconnect the middle layer IML and the second electrode EL2. Since the display panel DP-1 may further include the separator SPR, a second electrode EL2 independent of each of the light emitting portions EP1, EP2, and EP3 may be provided.

The separator SPR may include an organic insulation material. The separator SPR may have a reverse tapered shape on a cross-section. Referring to FIG. 8C, an angle θ (hereinafter, a taper angle θ) formed by a side surface SPR_W of the separator SPR with respect to an upper surface of the pixel definition film PDL may be an obtuse angle. However, this is only an example, and as long as the separator SPR can electrically disconnect the second electrode EL2 for each pixel, the taper angle θ may be set in various ways.

In an upper portion the separator SPR, a dummy layer UP may be disposed. The dummy layer UP may include a first dummy layer UP1 disposed on the separator SPR and a second dummy layer UP2 disposed on the first dummy layer UP1. The first dummy layer UP1 and the middle layer IML may be formed in the same process and include the same material. The second dummy layer UP2 and the second electrode EL2 may be formed in the same process and include the same material.

As illustrated in FIG. 8C, in an embodiment, the second electrode EL2 may include a first end portion EN1a, and the second dummy layer UP2 may include a second end portion EN2a. The first end portion EN1a may be spaced apart from the separator SPR and be disposed on the pixel definition film PDL. The second end portion EN2a may be separated from the first end portion EN1a and disposed on the side surface SPR_W of the separator SPR.

According to the disclosure, even if there is no separate patterning process for the second electrode EL2 or the middle layer IML, by preventing the second electrode EL2 or the middle layer IML from being formed in a lower portion of the side surface SPR_W of the separator SPR, it may be possible to allow the second electrode EL2 or the middle layer IML to be separated for each pixel. As long as the second electrode EL2 or the middle layer IML can be electrically disconnected between adjacent pixels, the shape of the separator SPR may be changed in various ways, and is not limited to any one embodiment.

According to the disclosure, since the display panel DP-1 may further include the connection wire CN, the driver connection part CD and the emission connection part CE may be provided at positions spaced apart in a plan view. Since the display panel DP-1 may further include the separator SPR, a second electrode EL2 independent of each pixel may be provided without the addition of a separate patterning process. Since the tip portion TP is formed in the connection wire CN, a stable connection between the connection wire CN and the second electrode EL2 may be implemented in the display panel DP-1.

A blocking pattern BKP0 may be connected to a connection wire CNW. In an embodiment, it is illustrated that the connection wire CNW and electrode patterns W1, W2, W11, and W21 are disposed on (or in) the same layer, but this is only an example, and the connection wire CNW and the electrode patterns W1, W2, W11, and W21 may be disposed on (or in) different layers, or the connection wire CNW and the blocking pattern BKP0 may be disposed on (or in) the same layer, but embodiments of the disclosure are not limited thereto.

The blocking pattern BKP0 and the connection wire CN may be disposed on (or in) the same layer. The blocking pattern BKP0 and the connection wire CN may have the same layered structure. For example, the blocking pattern BKP0 may have a stacking structure including first to third layers L1, L2, and L3. Accordingly, the blocking pattern BKP0 and the connection wire CN may be simultaneously formed through one mask, and thus, a process may be simplified.

This is only an example, and the blocking pattern BKP0 may have a different layered structure from that of the connection wire CN, or may be disposed on (or in) a layer different than the connection wire CN, and is not limited to any one embodiment.

The blocking pattern BKP0 may be disposed spaced apart from the connection wire CN in a plan view. Particularly, the blocking pattern BKP0 is spaced apart from the driver connection part CD (or the emission connection part CE) in a plan view. Accordingly, although the blocking pattern BKP0 and the connection wire CN are disposed on (or in) the same layer, an electrical short circuit between the blocking pattern BKP0 and the connection wire CN may be prevented. However, this is only an example, and as long as the blocking pattern BKP0 is not electrically short-circuited with the connection wire CN, the blocking pattern BKP0 and the connection wire CN may be disposed on (or in) different layers and overlap each other in a plan view, but are not limited to any one embodiment.

The blocking pattern BKP0 may be connected to the connection wire CNW. As described above, the connection wire CNW may transmit a constant voltage, and may transmit, for example, a power voltage. In an embodiment, it is illustrated that the connection wire CNW passes through a light emitting region, but embodiments of the disclosure are not limited thereto, and the connection wire CNW may be disposed in a peripheral region, and the blocking pattern BKP0 may be extended to the peripheral region, thereby achieving the connection in the peripheral region.

According to the disclosure, since the blocking pattern BKP0 of the display panel DP-1 is not electrically short-circuited with the connection wire CN, electrical shielding between the first transistor T1 and the first electrode EL1 may be stably implemented even if the connection wire CN is present. Therefore, an image having uniform luminance may be displayed even on a display panel DP-1 in which the emission connection part CE and the driver connection part CD are designed at positions spaced apart in a plan view.

FIG. 9A is a schematic plan view illustrating a portion of a display panel according to an embodiment of the disclosure. FIG. 9B is a schematic perspective view illustrating a portion of the display panel illustrated in FIG. 9A. FIG. 9C is a schematic plan view of one light emitting unit and one driving unit which are illustrated in FIG. 9A. Hereinafter, with reference to FIG. 9A to FIG. 9C, the disclosure will be described.

Referring to FIG. 9A and FIG. 9B, a display panel DP-2 may include a display region DA overlapping a panel driver DC in a plan view. Specifically, multiple light emitting units EPU may be provided and disposed in the display region DA. The light emitting units EPU may be arranged in the first direction DR1 and the second direction DR2. Therefore, the light emitting units EPU may be arranged in a matrix form.

The display panel DP-2 may include a first region AR1, second regions AR2, and third regions AR3. The first region AR1, the second regions AR2, and the third regions AR3 may be arranged in the first direction DR1. The first region AR1 may be disposed between the second regions AR2. The third regions AR3 may be adjacent to an edge of the display region DA or to a peripheral region NDA. Among the first to third regions AR1, AR2, and AR3, the third regions AR3 may be regions relatively more adjacent to the peripheral region NDA in the first direction DR1, and the first region AR1 may be a region farthest from the peripheral region NDA in the first direction DR1. The second regions AR2 may be regions disposed between first region AR1 and the third regions AR3.

The light emitting units EPU may be disposed in the first region AR1, the second region AR2, and the third region AR3. The panel driver DC may overlap at least a portion of the display region DA. Light emitting units EPU disposed in the third regions AR3 may overlap the panel driver DC in a plan view. In an embodiment, the panel driver DC may include at least one of the above-described scan driver SDC and emission driver EDC, but is not limited thereto.

One light emitting unit EPU may include first to third light emitting portions EP-R, EP-G, and EP-B. One pixel driving unit PDU may include first to third pixel drivers PDC_R, PDC_G, and PDC_B respectively driving the first to third light emitting portions EP_R, EP_G, and EP_B. The first to third pixel drivers PDC_R, PDC_G, and PDC_B may be arranged along the first direction DR1. The first to third pixel drivers PDC_R, PDC_G, and PDC_B may include the first to third connection transistors TR_R, TR_G, and TR_B respectively connected to the first to third light emitting portions EP_R, EP_G, and EP_B. Each of the first to third connection transistors TR_R, TR_G, and TR_B may be a driving transistor, but is not limited thereto.

Referring to FIG. 9B and FIG. 9C, a width in the first direction DR1 occupied by six pixel driving units PDU, which are respectively connected to six light emitting units EPU, may be smaller than a width in the first direction DR1 occupied by the six light emitting units EPU. Since a portion of the panel driver DC may be disposed in the third region AR3, which is a partial region of the display region DA, pixel driving units PDU should be disposed only in the first region AR1 and the second region AR2 of the display region DA, so that a width in the first direction DR1 occupied by a light emitting element layer LDL may be greater than a width in the first direction DR1 occupied by a driving element layer DDL.

Specifically, one light emitting unit EPU may have a first width WT1 in the first direction DR1. The pixel driving unit PDU-2 may have a second width WT2 in the first direction DR1. The second width WT2 may be less than the first width WT1. In the second direction DR2, the light emitting unit EPU and the pixel driving unit PDU may have the same width. Therefore, the pixel driving unit PDU may have an area smaller than that of the light emitting unit EPU.

According to the disclosure, the pixel driving unit PDU may have a width smaller than that of the light emitting unit EPU in the first direction DR1. Therefore, even in case that the light emitting units EPU and the pixel driving units PDU-2 are disposed in the same number in the display panel DP, disposition areas thereof may be different. In the first direction DR1, the disposition area of the light emitting units EPU having a larger width may be larger than the disposition area of the pixel driving units PDU having a smaller width. According to the disclosure, by designing the width of the pixel driving unit PDU to be smaller than the width of the light emitting unit EPU, it may be possible to provide the display region DA having an area larger than the area occupied by the driving element layer DDL. Accordingly, the display panel DP-2 having a narrow bezel may be provided.

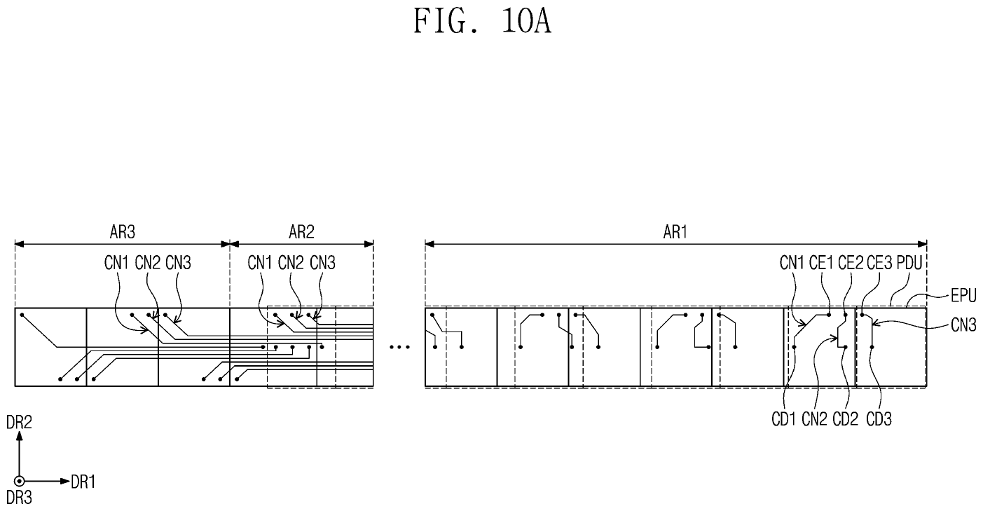

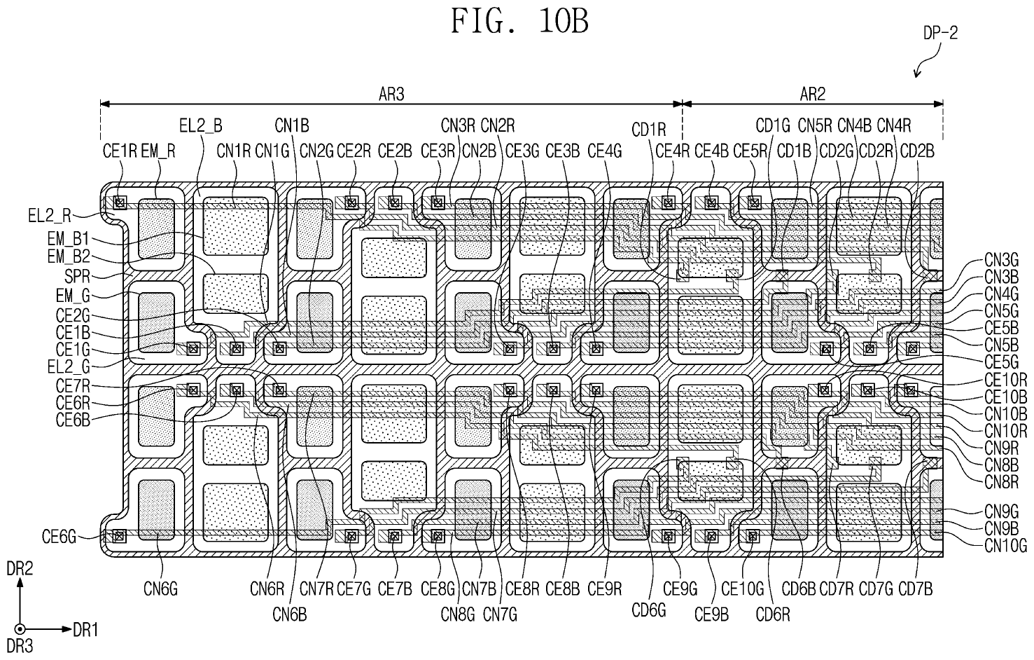

FIG. 10A is a schematic view illustrating one row of light emitting units and one row of driving units connected to the one row of the light emitting units. FIG. 10B is a schematic plan view illustrating a partial region of a display panel according to an embodiment of the disclosure. FIG. 10A schematically illustrates one row of light emitting units illustrated in FIG. 9A and one row of driving units connected to the one row of the light emitting units. FIG. 10B illustrates a third region AR3 and a second region AR2 in the region illustrated in FIG. 10A. Hereinafter, the disclosure will be described with reference to FIG. 10A and FIG. 10B.

Illustratively, in FIG. 10A, the second region AR2 and the third region AR3 on the left side from a central portion of a first region AR1 are illustrated. First and third connection wires CN1 and CN3 disposed on an upper side of one row are illustrated, and second and third connection wires CN2 and CN3 disposed on a lower side of one row are omitted. For case of description, in FIG. 10A, light emitting units EPU are illustrated with solid lines and pixel driving units PDU are illustrated with dotted lines.

Referring to FIG. 10A and FIG. 9C, the light emitting unit EPU may have a first width WT1 in the first direction DR1. The pixel driving unit PDU may have a second width WT2 in the first direction DR1. The second width WT2 may be less than the first width WT1. In the second direction DR2, the light emitting unit EPU and the pixel driving unit PDU may have the same width. Therefore, the pixel driving unit PDU may have an area smaller than that of the light emitting unit EPU.

The pixel driving units PDU may have a width smaller than that of the light emitting units EPU in the first direction DR1. Therefore, even in case that the light emitting units EPU and the pixel driving units PDU are disposed in the same number in the display panel DP-2, disposition areas thereof may be different. In the first direction DR1, the disposition area of the light emitting units EPU having a larger width may be larger than the disposition area of the pixel driving units PDU having a smaller width.

The light emitting units EPU may be disposed in the first, second, and third regions AR1, AR2, and AR3. However, the pixel driving units PDU may be disposed in the first and second regions AR1 and AR2, and may not be disposed in the third region AR3.

Depending on the size difference between the pixel driving units PDU and the light emitting units EPU, disposition positions of the pixel driving units PDU and the light emitting units EPU may vary. For example, positions of the pixel driving units PDU relative to the light emitting units EPU may vary. Specifically, a distance between each of the pixel driving units PDU and a light emitting unit EPU corresponding to each of the pixel driving units PDU may gradually increase from the center of the display panel DP (e.g., the center of the first region AR1) to an edge of the display panel DP-2 (e.g., the third region AR3).

Lengths of the first to third connection wires CN1, CN2, and CN3 may vary. For example, distances between first to third driver connection parts CD1, CD2, and CD3 and first to third emission connection parts CE1, CE2, and CE3 may vary.

Due to the structure as described above, first to third connection wires CN1, CN2, and CN3 extending from first to third emission connection parts CE1, CE2 and CE3 disposed in the third region AR3 may be longer than first to third connection wires CN1, CN2, and CN3 extending from first to third emission connection parts CE1, CE2 and CE3 disposed in the first region AR1 and the second region AR2.

First to third connection wires CN1, CN2, and CN3 extending from first to third emission connection parts CE1, CE2 and CE3 disposed in the second region AR2 may be longer than first to third connection wires CN1, CN2, and CN3 extending from first to third emission connection parts CE1, CE2 and CE3 disposed in the first region AR1.

In a central portion of the first region AR1, first to third connection wires CN1, CN2, and CN3 may not extend in the first direction DR1. However, as the distance between a pixel driving unit PDU and a light emitting unit EPU corresponding to each other increases in the first direction DR1, at least one of the first to third connection wires CN1, CN2, and CN3 may extend in the first direction DR1.

As the distance between a pixel driving unit PDU and a light emitting unit EPU corresponding to each other increases in the first direction DR1, the first to third connection wires CN1, CN2, and CN3 may extend parallel to each other in the first direction DR1. As the distance between a pixel driving unit PDU and a light emitting unit EPU corresponding to each other increases, the number of the first to third connection wires CN1, CN2, and CN3 extending parallel to each other in the first direction DR1 may increase.

For example, the longer the first to third connection wires CN1, CN2, and CN3, the first to third connection wires CN1, CN2, CN3 may be extended longer in the first direction DR1. In the second region AR2, first to third connection wires CN1, CN2, and CN3 may extend parallel to each other in the first direction DR1 and be arranged in the second direction DR2. In the second region AR2, at least four first to third connection wires CN1, CN2, and CN3 may be extended parallel to each other in the first direction DR1 and be arranged in the second direction DR2.

The display panel DP-2 may have a left-right symmetrical structure. Accordingly, although not illustrated, from the central portion of the first region AR1 to the right side thereof, the second and third regions AR2 and AR3 may have a similar configuration.

Referring to FIG. 10B, the display panel DP-2 may include multiple second electrodes EL2_R, EL2_G, and EL2_B separated by a separator SPR, and multiple light emitting patterns EM_R, EM_G, EM_B1, and EM_B2 disposed in a region separated by the separator SPR and respectively overlapping the second electrodes EL2_R, EL2_G, and EL2_B. Each of the light emitting patterns EM_R, EM_G, EM_B1, and EM_B2 may correspond to the above-described light emitting layer EML (see FIG. 6). Among the light emitting patterns EM_R, EM_G, EM_B1, and EM_B2, third light emitting patterns EM_B1 and EM_B2 constituting a third light emitting element may include two patterns spaced apart from each other in the second direction DR2. However, this is only an example, and the third light emitting patterns EM_B1 and EM_B2 may be provided as one pattern, and are not limited to any one embodiment.

As described above, emission connection parts CE1R, CE1G, CE1B, CE2R, CE2G, CE2B, CE3R, CE3G, CE3B, CE4R, CE4G, CE4B, CE5R, CE5G, and CE5B of a first row may be separated and disposed on an upper side or a lower side of the corresponding row, and driver connection parts CD1R, CD1G, CD1B, CD2R, CD2G, and CD2B may be disposed in one line along the first direction DR1 at a middle position of the corresponding row. In the same manner, emission connection parts CE6R, CE6G, CE6B, CE7R, CE7G, CE7B, CE8R, CE8G, CE8B, CE9R, CE9G, CE9B, CE10R, CE10G, and CE10B of a second row may be separated and disposed on an upper side or a lower side of the corresponding row, and driver connection parts CD6R, CD6G, CD6B, CD7R, CD7G, and CD7B may be disposed in one line along the first direction DR1 at a middle position of the corresponding row.

Light emitting portions overlapping the driver connection parts CD1R, CD1G, CD1B, CD2R, CD2G, CD2B, CD6R, CD6G, CD6B, CD7R, CD7G, and CD7B may be light emitting portions disposed in the second region AR2, and light emitting portions not overlapping the driver connection parts CD1R, CD1G, CD1B, CD2R, CD2G, CD2B, CD6R, CD6G, CD6B, CD7R, CD7G, and CD7B may be light emitting portions disposed in the third region AR3. As a light emitting element and a pixel driver may be disposed at non-overlapping positions in a plan view, the light emitting element and the pixel driver may be electrically connected through connection wires.

Some connection wires CN1R, CN2R, CN2B, CN3R, CN4R, CN4B, and CN5R of connection wires CN1R, CN1G, CN1B, CN2R, CN2G, CN2B, CN3R, CN3G, CN3B, CN4R, CN4G, CN4B, CN5R, CN5G, and CN5B disposed in the first row may be extended to an upper side of the driver connection parts CD1R, CD1G, CD1B, CD2R, CD2G, and CD2B and may provide emission connection parts CE1R, CE2R, CE2B, CE3R, CE4R, CE4B, and CE5R disposed on the upper side. Other connection wires CN1G, CN1B, CN2G, CN3G, CN3B, CN4G, CN5G, and CN5B of the connection wires CN1R, CN1G, CN1B, CN2R, CN2G, CN2B, CN3R, CN3G, CN3B, CN4R, CN4G, CN4B, CN5R, CN5G, and CN5B disposed in the first row may be extended to a lower side of the driver connection parts CD1R, CD1G, CD1B, CD2R, CD2G, and CD2B and may provide emission connection parts CE1G, CE1B, CE2G, CE3G, CE3B, CE4G, CE5G, and CE5B disposed on the lower side.

Some connection wires CN6R, CN6B, CN7R, CN8R, CN8B, CN9R, CN10R, and CN10B of connection wires CN6R, CN6G, CN6B, CN7R, CN7G, CN7B, CN8R, CN8G, CN8B, CN9R, CN9G, CN9B, CN10R, CN10G, and CN10B disposed in the second row may be extended to an upper side of the driver connection parts CD6R, CD6G, CD6B, CD7R, CD7G, and CD7B and may provide emission connection parts CE6R, CE6B, CE7R, CE8R, CE8B, CE9R, CE10R, and CE10B disposed on the upper side. Other connection wires CN6G, CN7G, CN7B, CN8G, CN9G, CN9B, and CN10G of the connection wires CN6R, CN6G, CN6B, CN7R, CN7G, CN7B, CN8R, CN8G, CN8B, CN9R, CN9G, CN9B, CN10R, CN10G, and CN10B disposed in the second row may be extended to a lower side of the driver connection parts CD6R, CD6G, CD6B, CD7R, CD7G, and CD7B and may provide emission connection parts CE6G, CE7G, CE7B, CE8G, CE9G, CE9B, and CE10G disposed on the lower side.

The connection wires CN1R, CN2R, CN2B, CN3R, CN4R, CN4B, and CN5R extended to the upper side of the driver connection parts CD1R, CD1G, CD1B, CD2R, CD2G, and CD2B may be disposed in a space between the driver connection parts CD1R, CD1G, CD1B, CD2R, CD2G, and CD2B and the upper emission connection parts CE4R, CE4B, and CE5R. In the same manner, the connection wires CN1G, CN1B, CN2G, CN3G, CN3B, CN4G, CN5G, and CN5B extended to the lower side of the driver connection parts CD1R, CD1G, CD1B, CD2R, CD2G, and CD2B may be disposed in a space between the driver connection parts CD1R, CD1G, CD1B, CD2R, CD2G, and CD2B and the lower emission connection parts CE5G and CE5B.

According to the disclosure, electrical connection between light emitting portions disposed in the third region AR3 and pixel drivers disposed in the second region AR2 may be facilitated through a connection wire. By designing the length of a connection wire in various ways, the degree of freedom in designing the disposition of a light emitting portion may be improved regardless of the position of a pixel driver.

According to the disclosure, the blocking pattern BKP (see FIG. 4A) may be disposed spaced apart from connection wires in a plan view. In case that the blocking pattern BKP is disposed on (or in) the same layer with the connection wires, the blocking pattern BKP may have a shape spaced apart from or not overlapping the connection wires in a plan view. In other embodiments, the blocking pattern BKP may be disposed on (or in) a layer different than the connection wires. Since the blocking pattern BKP may be spaced apart from the connection wires, electrical connection between the blocking pattern BKP and the connection wires may be prevented.

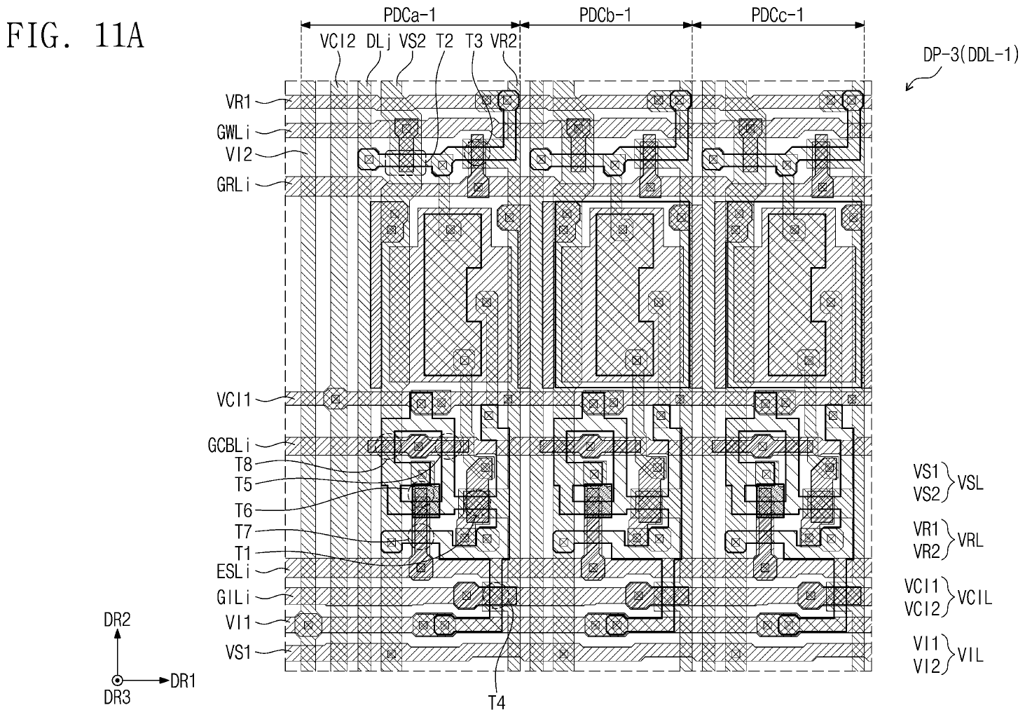

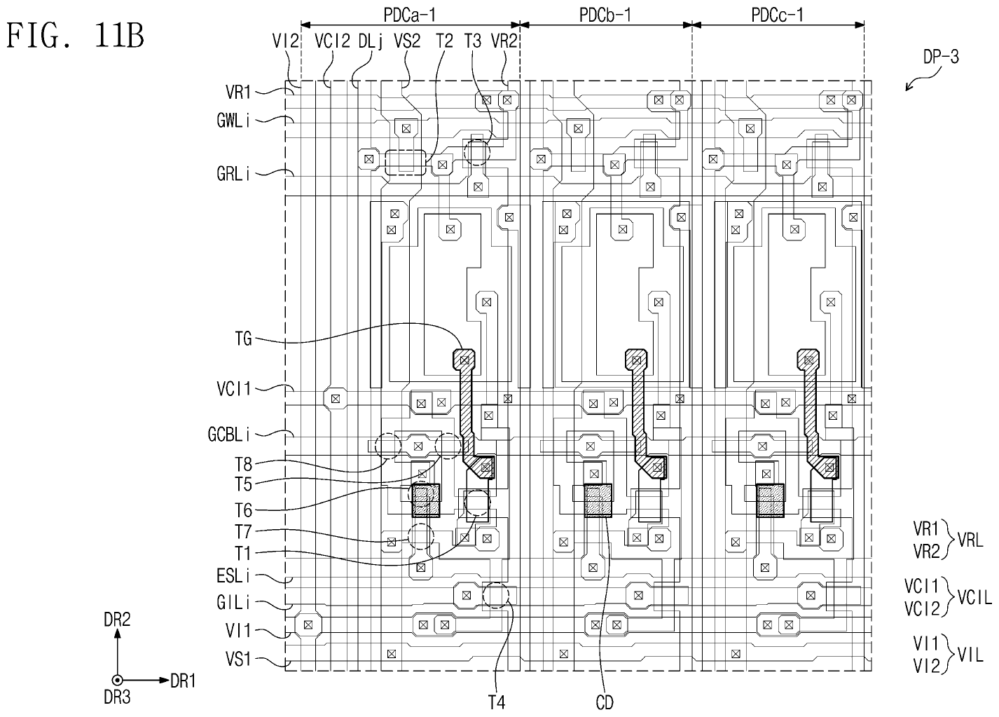

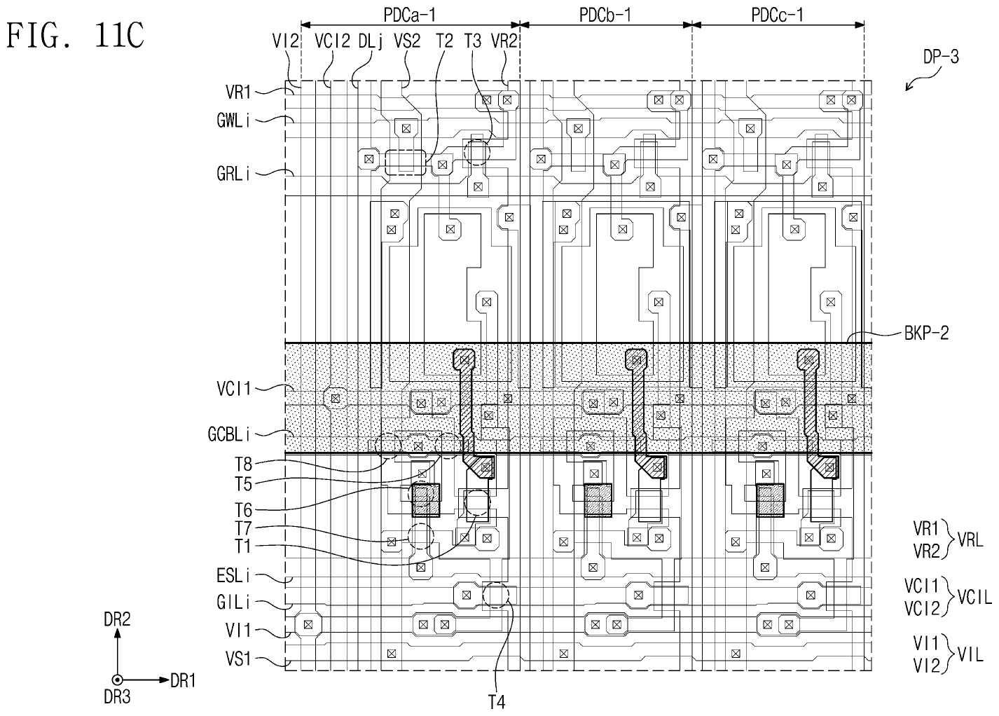

FIG. 11A to FIG. 11C are schematic plan views illustrating a portion of a display panel according to an embodiment of the disclosure. FIG. 11A may be a drawing corresponding to FIG. 5A, and FIG. 11A to FIG. 11C may be drawings illustrating a driving element layer DDL-1 of the pixel PXij-1 illustrated in FIG. 2B. Hereinafter, redundant descriptions will be omitted.

Referring to FIG. 11A, in a display panel DP-3, a horizontal voltage line VR1 constituting a reference voltage line VRL, a write scan line GWLi, a reset scan line GRLi, a horizontal voltage line VCI1 (hereinafter, a second horizontal voltage line VCI1) constituting a compensation initialization voltage line VCIL, an initialization compensation scan line GCBLi, an emission line ESLi, a first initialization scan line GILi, a horizontal voltage line VI1 constituting an initialization voltage line VIL, and a horizontal voltage line VS1 constituting a second power line VSL are each extended along the first direction DR1 and arranged along the second direction DR2.

A vertical voltage line VI2 constituting the initialization voltage line VIL, a vertical voltage line VCI2 constituting the compensation initialization voltage line VCIL, a data line DLj, a vertical voltage line VS2 constituting the second power line VSL, and a vertical voltage line VR2 constituting the reference voltage line VRL may each be extended along the second direction DR2 and arranged along the first direction DR1.

Referring to a pixel driver PDCa-1 (pixel drivers PDCb-1 and PDCc-1 similar to the pixel driver PDCa-1) disposed on the leftmost side in the region illustrated in FIG. 11A, a second transistor T2 and a third transistor T3 may be disposed along the first direction DR1 between the write scan line GWLi and the reset scan line GRLi, and may be connected to the write scan line GWLi and the reset scan line GRLi, respectively. Capacitors C1 and C2 (e.g. refer to FIG. 2B) may be disposed between the reset scan line GRLi and the second horizontal voltage line VCI1, and an eighth transistor T8 and a fifth transistor T5 may be disposed along the initialization compensation scan line GCBLi. A sixth transistor T 6, a seventh transistor T7, and a first transistor T1 may be disposed between the initialization compensation scan line GCBLi and the emission line ESLi, and a fourth transistor T4 may be disposed overlapping the first initialization scan line GILi between the emission line ESLi and the fourth horizontal power line VI1.

The first transistor T1 may be disposed on the right side of the sixth transistor T6 and the seventh transistor T7. For ease of description, FIG. 11B illustrates a driver connection part CD and a gate TG of the first transistor T1 in an emphasized way. The driver connection part CD and the gate TG of the first transistor T1 may be disposed spaced apart from each other in a plan view.

Referring to FIG. 11C, a blocking pattern BKP-2 may be disposed on (or in) the same layer as the driver connection part CD, and may overlap at least a portion of the gate TG of the first transistor T1. The blocking pattern BKP-2 may have a bar shape extended along the first direction DR1. The blocking pattern BKP-2 may overlap, in a plan view, gates TG of multiple first transistors T1 disposed in the same row. Accordingly, adjacent light emitting portions may be simultaneously and electrically shielded through one blocking pattern BKP-2. Therefore, the occurrence of a luminance deviation between the light emitting portions may be reduced, and an image having uniform luminance may be displayed.

According to the disclosure, it may be possible to provide a display panel which displays an image having an improved luminance difference for each region. According to the disclosure, it may be possible to prevent stains or a moire phenomenon from occurring in an image displayed on a display panel, and to provide an image having uniform luminance.

Although the disclosure has been described with reference to embodiments of the disclosure, it will be understood by those skilled in the art that various modifications and changes in form and details may be made therein without departing from the spirit and scope of the disclosure. Accordingly, the technical scope of the disclosure is not intended to be limited to the contents set forth in the detailed description of the specification.

What is claimed is:

1. A display panel, comprising:
a light emitting portion including:
an anode;
a cathode; and
an organic layer disposed between the anode and the cathode and that emits light;
a pixel driver electrically connected to the light emitting portion, and including a first transistor;
a connection wire disposed on a different layer than the first transistor, and electrically connecting the light emitting portion and the pixel driver; and
a conductive pattern disposed between the first transistor and the light emitting portion,
wherein the conductive pattern overlaps at least a portion of the anode and at least a portion of a gate of the first transistor in a plan view.

2. The display panel of claim 1, wherein the conductive pattern receives a constant voltage.

3. The display panel of claim 2, wherein the conductive pattern and the anode receive a same voltage.

4. The display panel of claim 2, wherein the conductive pattern and the cathode receive a same voltage.

5. The display panel of claim 1, wherein
the organic layer comprises a light emitting pattern, and
the light emitting pattern is spaced apart from the conductive pattern in a plan view.

6. The display panel of claim 1, wherein
the connection wire extends in a first direction, and
the conductive pattern extends in a second direction intersecting the first direction.

7. The display panel of claim 1, wherein
the first transistor and the light emitting portion are each provided in plurality and arranged along a first direction,
first transistors are respectively electrically connected to light emitting portions different from each other, and
the conductive pattern overlaps gates of the first transistors in a plan view.

8. The display panel of claim 7, wherein
the conductive pattern and the connection wire are disposed in a same layer, and
the conductive pattern is spaced apart from the connection wire in a plan view.

9. The display panel of claim 7, wherein the conductive pattern is disposed in a layer different than the connection wire.

10. The display panel of claim 7, wherein anodes of the light emitting portions are connected to each other and have a shape of a single body.

11. The display panel of claim 7, further comprising:
a gate driver that provides a gate signal to pixel drivers corresponding to the light emitting portions, wherein
a subset of the light emitting portions overlap the gate driver in a plan view.

12. The display panel of claim 11, wherein the subset of the light emitting portions are spaced apart from the conductive pattern in a plan view.

13. The display panel of claim 11, wherein
a plurality of connection wires electrically connected to the light emitting portions and the pixel drivers corresponding to the light emitting portions comprise:
a first connection wire electrically connected to a light emitting portion among the light emitting portions which is disposed in a first region spaced apart from the gate driver;
a second connection wire electrically connected to a light emitting portion among the light emitting portions which is disposed in a second region more adjacent to the gate driver than the first region; and
a third connection wire electrically connected to a light emitting portion among the light emitting portions which is disposed in a third region positioned between the first region and the second region in the first direction, and
a length of the second connection wire is greater than a length of the first connection wire.

14. The display panel of claim 1, wherein the first transistor comprises an N-type semiconductor.

15. The display panel of claim 1, wherein the pixel driver further comprises a second transistor electrically connected to the connection wire and spaced apart from the first transistor.

16. A display panel, comprising:
a driving element layer including a plurality of pixel drivers each having a transistor;
a light emitting element layer disposed on the driving element layer, and including a separator and a plurality of light emitting elements;
a plurality of connection wires each including a side electrically connected to a corresponding one of the plurality of light emitting elements and another side electrically connected to a corresponding one of the plurality of pixel drivers; and
a conductive pattern disposed between the driving element layer and the light emitting element layer, and overlapping transistors of the plurality of pixel drivers in a plan view, wherein
each one of the plurality of light emitting elements includes:
an anode;
an organic layer disposed on the anode and separated from an adjacent light emitting portion by the separator; and
a cathode disposed on the organic layer and separated from the adjacent light emitting portion by the separator, and
the plurality of connection wires are respectively electrically connected to cathodes of the plurality of light emitting elements.

17. The display panel of claim 16, wherein
a side surface of the another side of each of the connection wires has an undercut shape on a cross-section, and
the cathode of each of the light emitting elements is electrically connected to the side surface.

18. The display panel of claim 17, wherein
a gate of each of the transistors is extended in a first direction, and
the conductive pattern is extended in a second direction intersecting the first direction.

19. The display panel of claim 18, wherein the conductive pattern overlaps, in a plan view, a plurality of gates arranged along the second direction among the respective gates of the transistors.

20. The display panel of claim 18, wherein the conductive pattern comprises:
a plurality of patterns arranged along the second direction, wherein
the plurality of patterns respectively overlap, in a plan view, a plurality of gates arranged along the second direction among the respective gates of the transistors.

21. The display panel of claim 16, wherein anodes of the plurality of light emitting elements are connected to each other and have a shape of a single body.

22. The display panel of claim 16, wherein
the conductive pattern and the connection wires are disposed in a same layer, and
the conductive pattern is spaced apart from the connection wires in a plan view.

23. The display panel of claim 16, wherein
the anode of each of the light emitting elements is provided with a first voltage, and
the conductive pattern receives the first voltage.
